(19) United States
(12) Patent Application Publication
(10) Pub. No.: US 2025/0383373 A1
(43) Pub. Date: Dec. 18, 2025

(54) MEASUREMENT MODULE ADAPTERS, PROBE ASSEMBLIES THAT INCLUDE THE MEASUREMENT MODULE ADAPTERS, PROBE SYSTEMS THAT INCLUDE THE PROBE ASSEMBLIES, AND RELATED METHODS

(71) Applicant: FormFactor, Inc., Livermore, CA (US)

(72) Inventors: Jörg Hertwig, Radeberg (DE); Giancarlo De Chirico, Rohnert Park, CA (US); Gavin Neil Fisher, Fenny Compton (GB)

(21) Appl. No.: 19/187,404

(22) Filed: Apr. 23, 2025

Related U.S. Application Data
(60) Provisional application No. 63/659,634, filed on Jun. 13, 2024.

(51) Int. Cl. G01R 1/30; G01R 1/067

(52) U.S. Cl. CPC G01R 1/30; G01R 1/06705

(57) ABSTRACT

Measurement module adapters, probe assemblies that include the measurement module adapters, probe systems that include the probe assemblies, and related methods are disclosed herein. The measurement module adapters are configured to operatively attach a measurement module and a probe arm to a manipulator of a probe system and include an adapter plate, a bracket assembly, a plurality of inserts, and a probe arm mount. The probe assemblies include a manipulator, a measurement module adapter, a probe arm, a probe, and a measurement module. The probe systems include a chuck, a manipulator mounting surface, and a probe assembly. The methods include methods of utilizing a probe system that includes a measurement module adapter.

### RELATED APPLICATION

This application claims priority to U.S. Provisional Patent Application No. 63/659,634, which was filed on Jun. 13, 2024, and the complete disclosure of which is hereby incorporated by reference.

### FIELD OF THE DISCLOSURE

The present disclosure relates generally to measurement module adapters, to probe assemblies that include the measurement module adapters, to probe systems that include the probe assemblies, and to related methods.

### BACKGROUND OF THE DISCLOSURE

Different measurement modules may be utilized in a probe system to perform corresponding tests on a device under test. It may be desirable to mount such measurement modules as near to corresponding probes of the probe system as is practical and/or permissible given spatial constraints, such as via mounting the measurement modules to a manipulator of the probe system. However, various measurement module types and/or different measurement module manufacturers may utilize different mounting configurations. As such, it historically has been necessary to create a custom fixture for each measurement module that will be utilized by a given probe system. This process is costly and time-consuming.

In addition, an operator of the given probe system often may wish to utilize different measurement modules at different times and/or to perform different corresponding tests. To do so, the operator may be required to catalog a variety of different fixtures, to store the variety of different fixtures, and to mount and demount the various fixtures when different measurement modules are desired to be used. This further increases operational costs and decreases efficiency. Thus, there exists a need for improved measurement module adapters, for improved probe assemblies that include the measurement module adapters, for improved probe systems that include the probe assemblies, and for related methods.

### SUMMARY OF THE DISCLOSURE

Measurement module adapters, probe assemblies that include the measurement module adapters, probe systems that include the probe assemblies, and related methods are disclosed herein. The measurement module adapters are configured to operatively attach a measurement module and a probe arm to a manipulator of a probe system and include an adapter plate, a bracket assembly, a plurality of inserts, and a probe arm mount. The adapter plate may include a manipulator-facing surface that defines an adapter plate mount configured to be operatively attached to the manipulator and/or a module-facing surface that defines a bracket assembly mount. The bracket assembly may be selectively and operatively affixed to the bracket assembly mount and may include a plurality of insert-receiving regions. The measurement module adapter may be configured to selectively permit adjustment of a relative orientation between the bracket assembly and the adapter plate along a first adjustment axis. A corresponding insert of the plurality of inserts may be selectively and operatively attached to the bracket assembly within a corresponding insert-receiving region of the plurality of insert-receiving regions. The corresponding insert may include a corresponding insert fastener configured to be operatively attached to the measurement module. Each insert and the corresponding insert-receiving region together may be configured to permit adjustment of a relative orientation between the corresponding insert fastener and the bracket assembly along a second adjustment axis that extends at least substantially perpendicular to the first adjustment axis. The probe arm mount may be configured to be operatively attached to the probe arm.

The probe assembly includes a manipulator and the measurement module adapter. The adapter plate mount of the measurement module adapter may be operatively attached to the manipulator. The probe assembly also includes a probe arm, which may be operatively attached to the probe arm mount, a probe, which may be operatively attached to the probe arm, and a measurement module, which may be operatively attached to the bracket assembly via the corresponding insert fastener of the plurality of inserts.

The probe system is configured to test a device under test and includes a chuck, a manipulator mounting surface, and the probe assembly. The chuck may define a support surface configured to support a substrate that includes the DUT, and the manipulator may be operatively attached to the manipulator mounting surface.

The methods are methods of utilizing a probe system and include disconnecting an initial measurement module from a probe of the probe system, such as via disconnection of an initial signal conduit from at least one of the initial measurement module and the probe. The methods also include detaching the initial measurement module from a measurement module adapter of the probe system, such as via disengagement of an initial plurality of insert fasteners of the measurement module adapter from the initial measurement module. The methods further include adjusting the measurement module adapter to interface with a subsequent measurement module, which differs from the initial measurement module. The adjusting may include operatively translating at least one insert fastener of the initial plurality of insert fasteners relative to at least one other insert fastener of the initial plurality of insert fasteners and within a translation plane that is parallel to a bracket assembly mount of the measurement module adapter. Additionally or alternatively, the adjusting may include replacing at least one insert of the measurement module adapter with a structurally different insert of the measurement module adapter. The methods also include attaching the subsequent measurement module to the measurement module adapter, such as via engagement of a subsequent plurality of insert fasteners of the measurement module adapter with the subsequent measurement module. The methods further include connecting the subsequent measurement module to the probe via a subsequent signal conduit.

### BRIEF DESCRIPTION OF THE DRAWINGS

FIG. 1 is a schematic illustration of examples of probe systems that include probe assemblies that include measurement module adapters, according to the present disclosure.

FIG. 2 is a schematic side view illustrating an example of a probe assembly that includes a measurement module adapter, according to the present disclosure.

FIG. 3 is a schematic side view illustrating the measurement module adapter of FIG. 2.

FIG. 4 is a schematic side view illustrating an example of a probe assembly that includes a measurement module adapter, according to the present disclosure.

FIG. 5 is a schematic side view illustrating an example of a probe assembly that includes a measurement module adapter, according to the present disclosure.

FIG. 6 is a schematic side view illustrating an example of a probe assembly that includes a measurement module adapter, according to the present disclosure.

FIG. 7 is a profile view of the probe assembly of FIG. 6.

FIG. 8 is a top view of the probe assembly of FIG. 6.

FIG. 9 is a bottom view of the probe assembly of FIG. 6.

FIG. 10 is a schematic side view illustrating a portion of the probe assemblies of FIGS. 2-9.

FIG. 11 is a schematic top view of the portion of the probe assembly that is illustrated in FIG. 10.

FIG. 12 is an exploded side view of the portion of the probe assembly that is illustrated in FIGS. 10-11.

FIG. 13 is an exploded top view of the portion of the probe assembly that is illustrated in FIGS. 10-12.

FIG. 14 is an exploded bottom view of the portion of the probe assembly that is illustrated in FIGS. 10-13.

FIG. 15 is a profile view of an example of an adapter plate of the measurement module adapters illustrated in FIGS. 2-14.

FIG. 16 is a side view of the adapter plate of FIG. 15.

FIG. 17 is a top view of the adapter plate of FIGS. 15-16.

FIG. 18 is a bottom view of the adapter plate of FIGS. 15-17.

FIG. 19 is a profile view of an example of a probe-proximate bracket of a bracket assembly of the measurement module adapters illustrated in FIGS. 2-14.

FIG. 20 is a side view of the probe-proximate bracket of FIG. 19.

FIG. 21 is a top view of the probe-proximate bracket of FIGS. 19-20.

FIG. 22 is a bottom view of the probe-proximate bracket of FIGS. 19-21.

FIG. 23 is a profile view of an example of a probe-distal bracket of the bracket assembly of the measurement module adapters illustrated in FIGS. 2-14.

FIG. 24 is a side view of the probe-distal bracket of FIG. 23.

FIG. 25 is a top view of the probe-distal bracket of FIGS. 23-24.

FIG. 26 is a bottom view of the probe-distal bracket of FIGS. 23-25.

FIG. 27 is a profile view of an example of an insert base of an insert of the measurement module adapters illustrated in FIGS. 2-14.

FIG. 28 is a top view of the insert base of FIG. 27.

FIG. 29 is a bottom view of the insert base of FIGS. 27-28.

FIG. 30 is a flowchart illustrating examples of methods of utilizing a probe system, according to the present disclosure.

### DETAILED DESCRIPTION AND BEST MODE OF THE DISCLOSURE

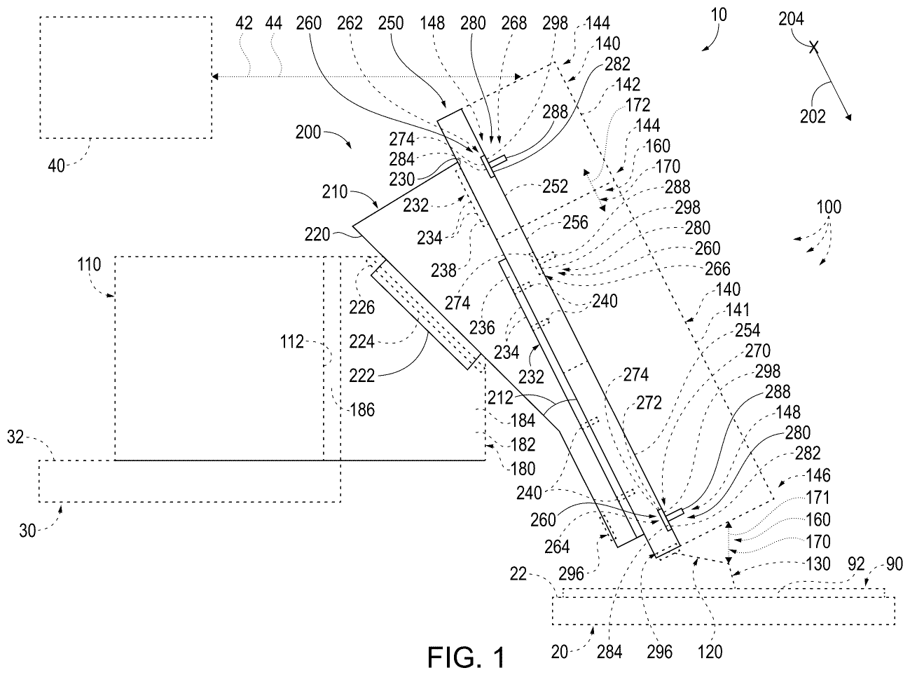

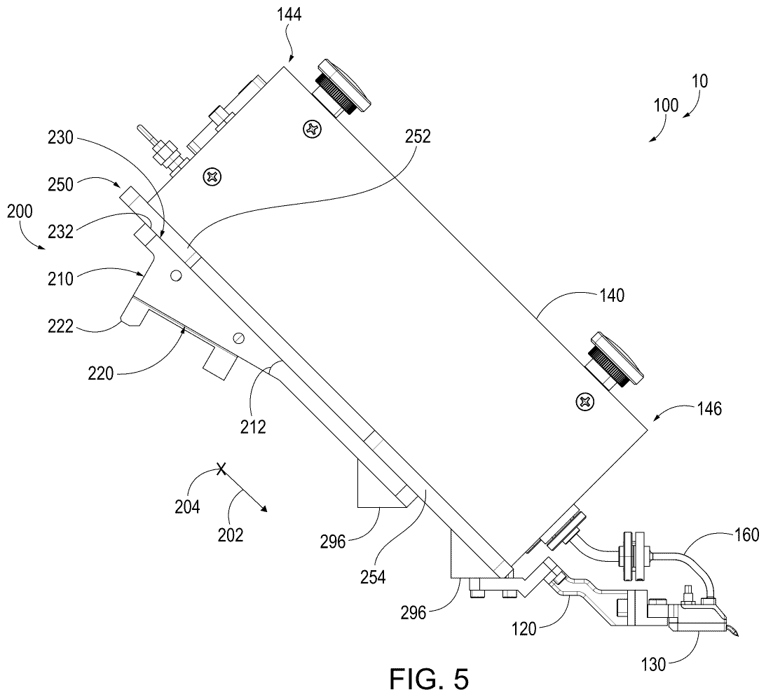

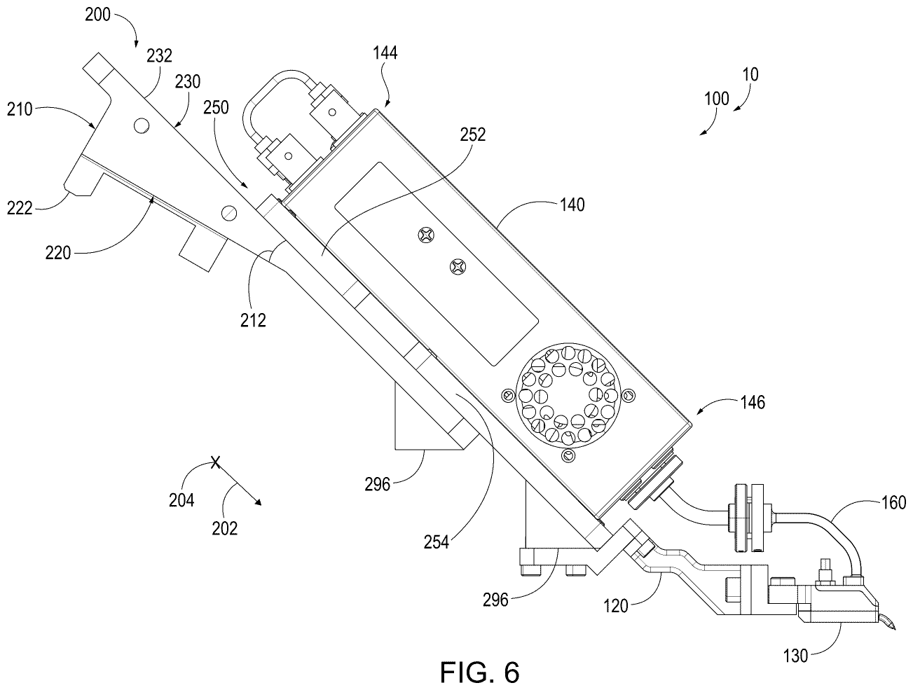

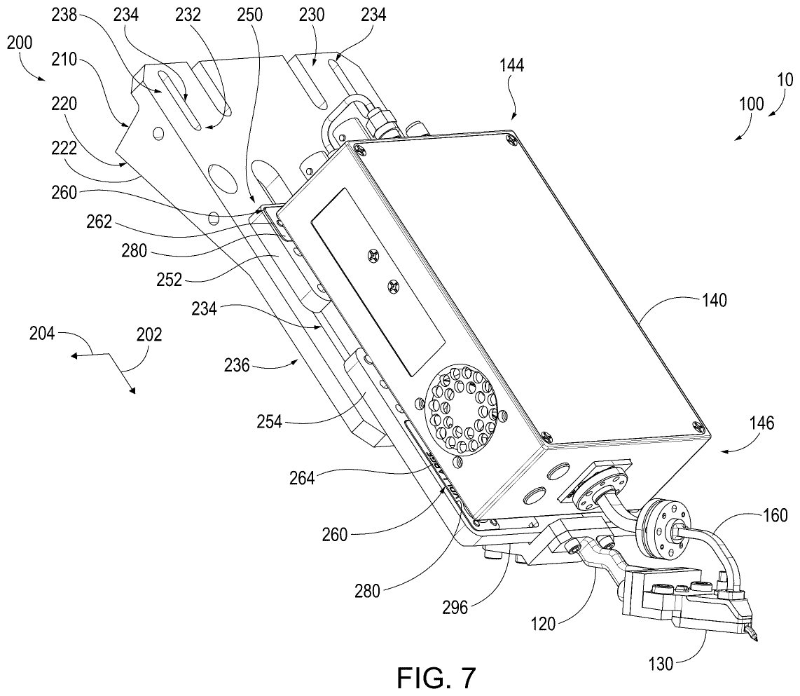

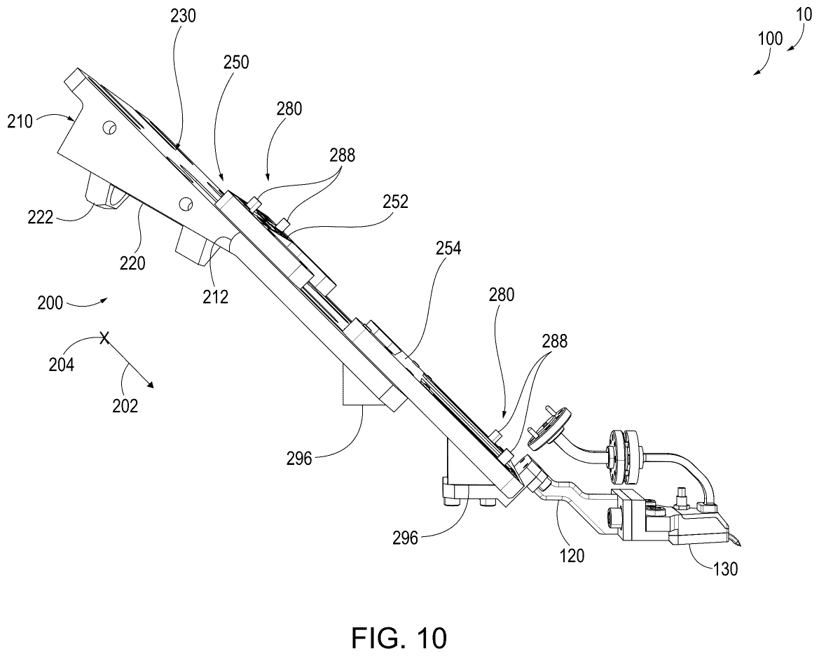

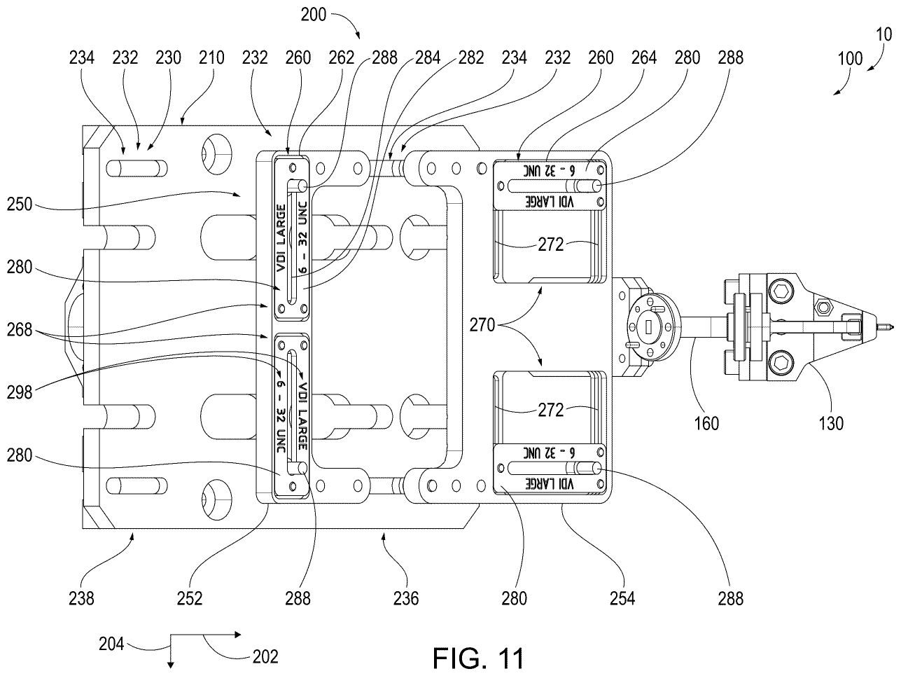

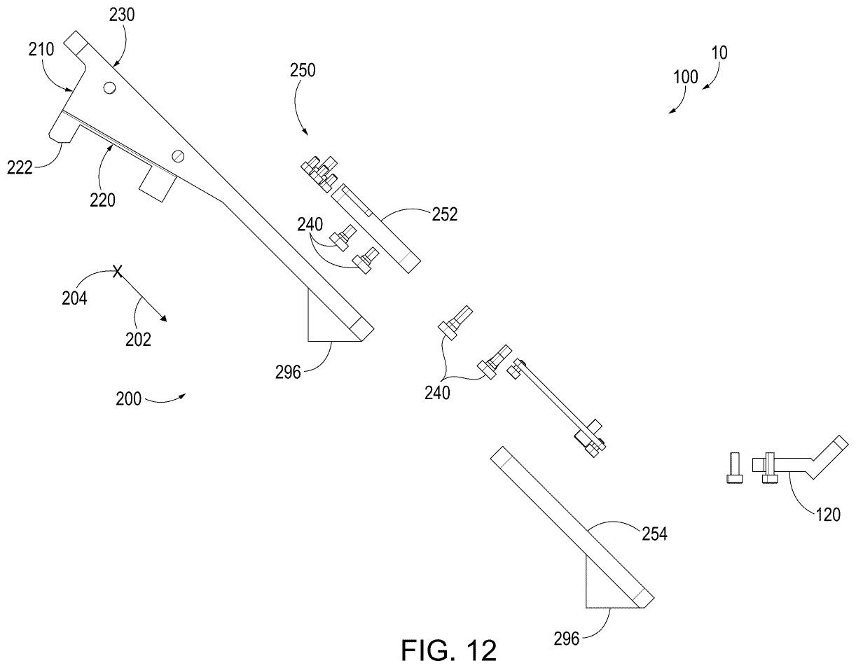

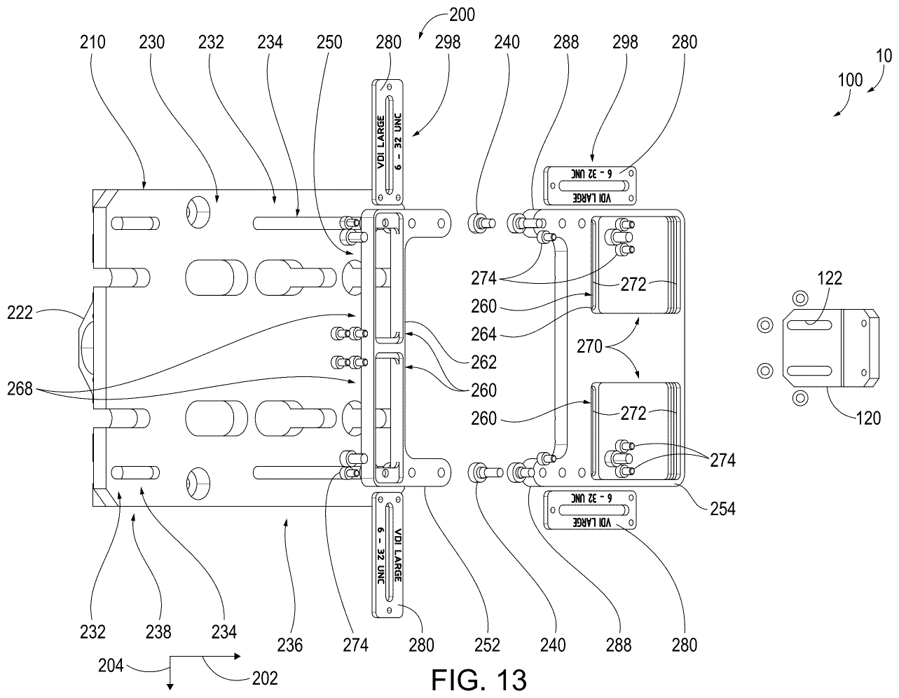

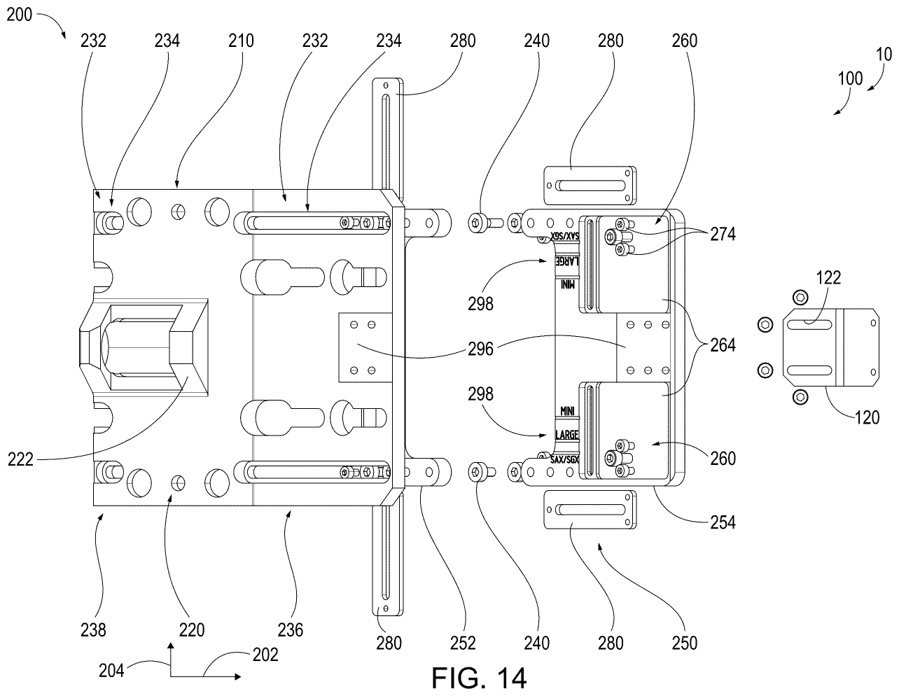

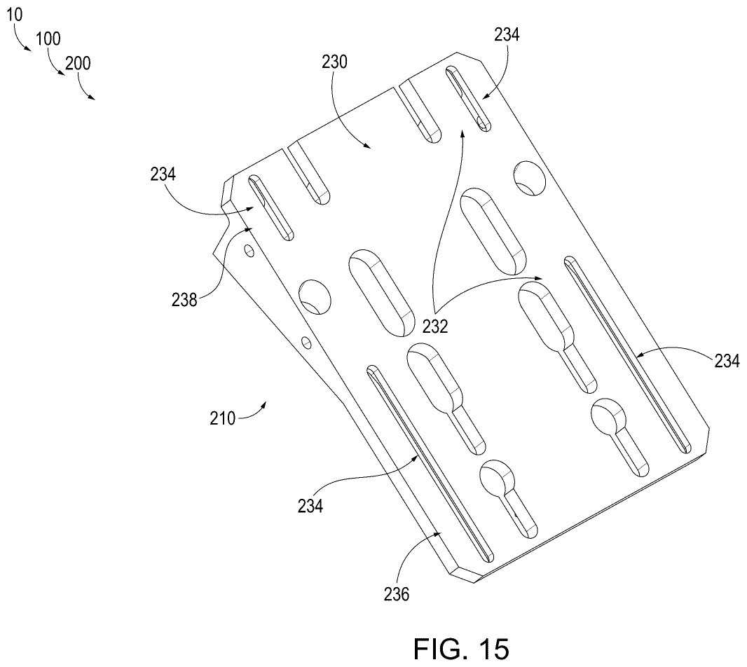

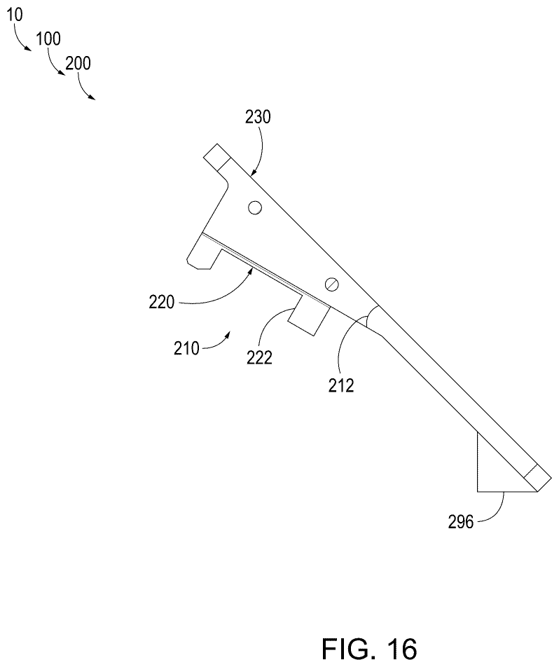

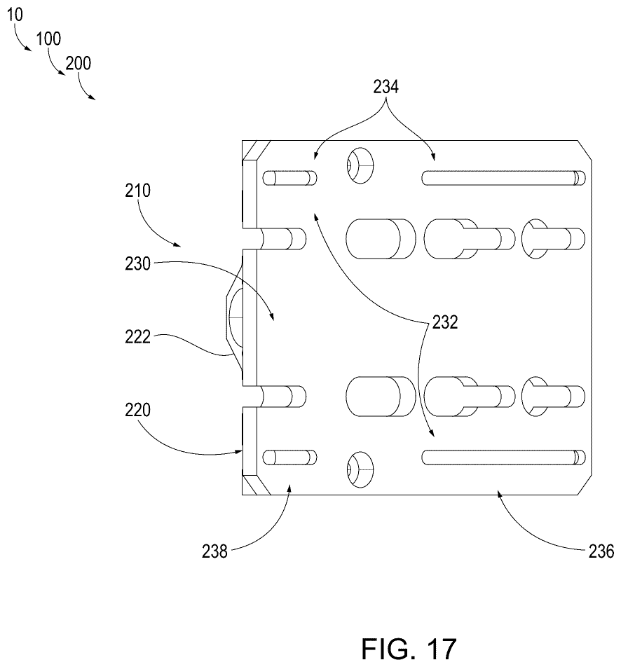

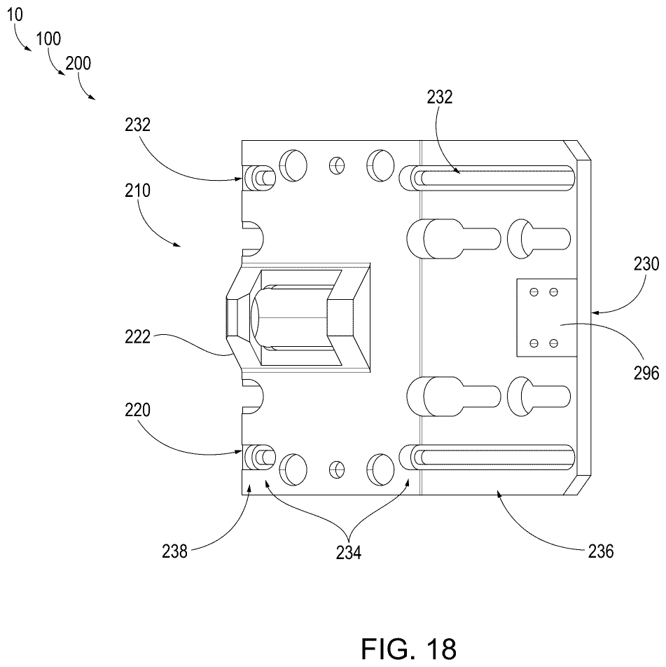

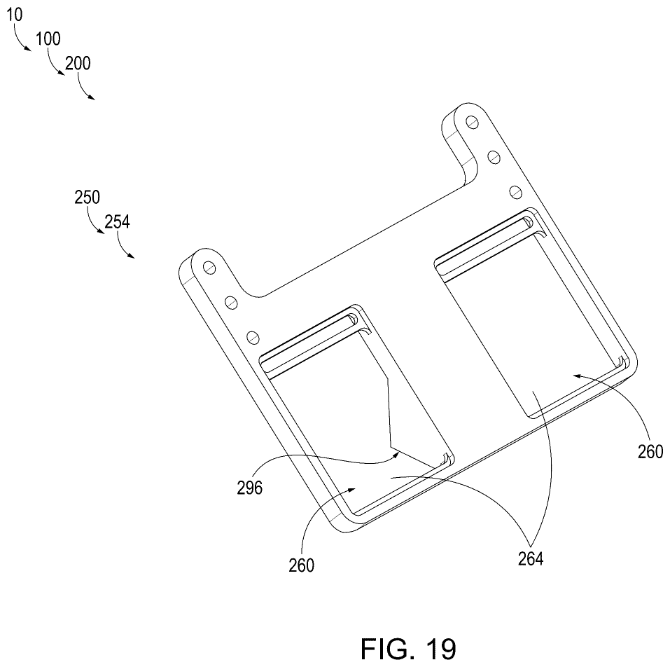

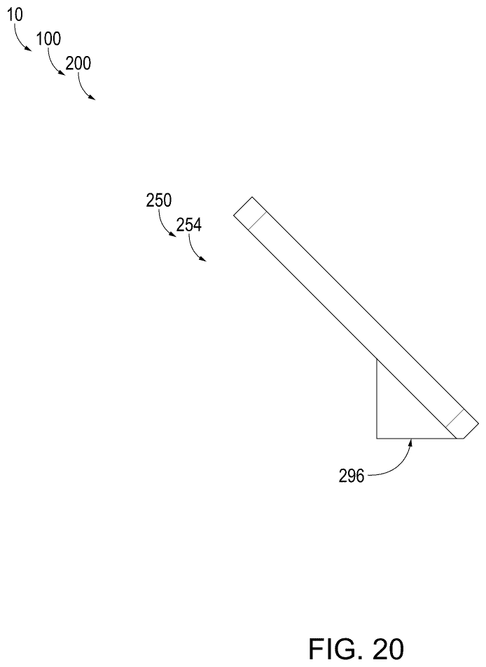

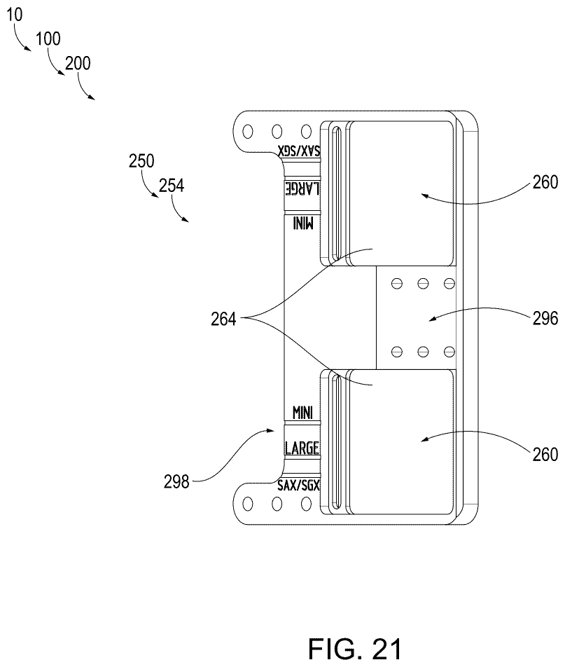

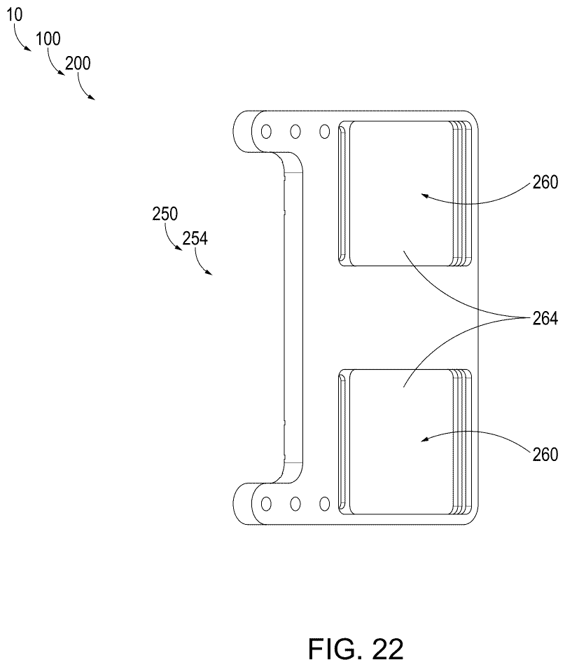

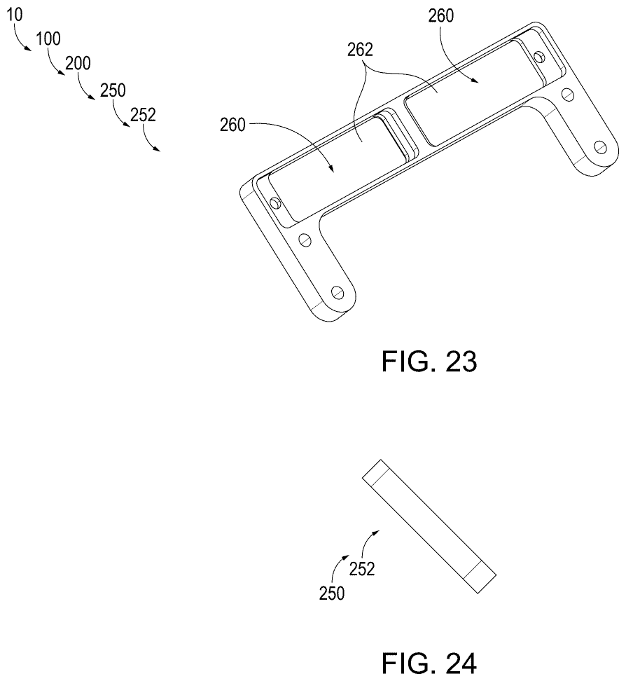

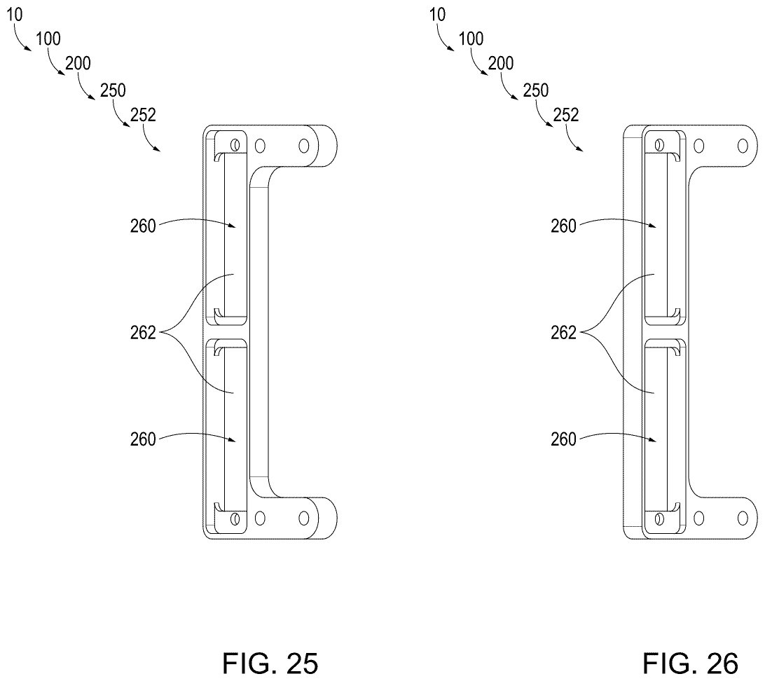

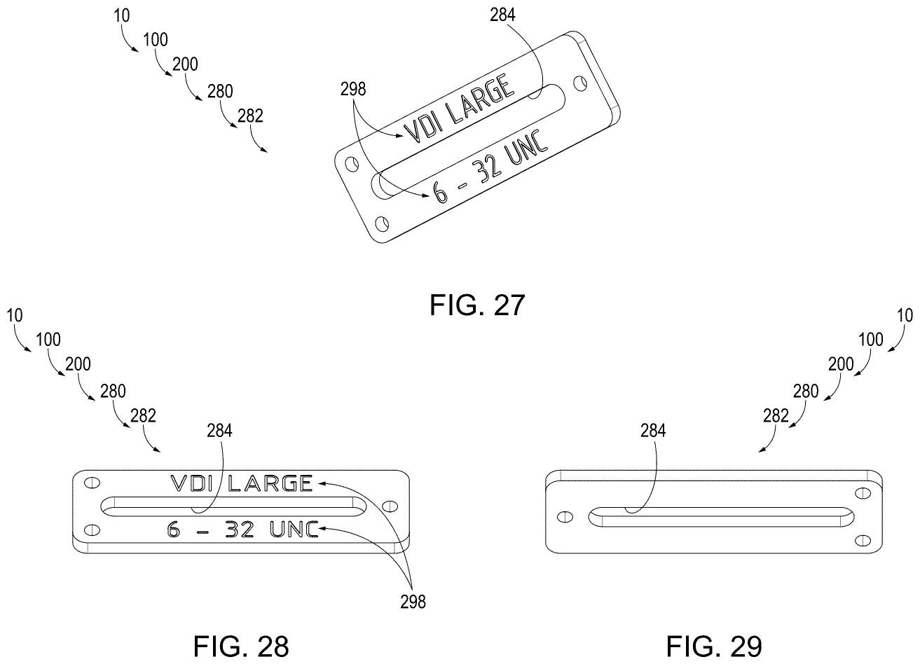

FIGS. 1-30 provide examples of probe systems 10, of probe assemblies 100, of measurement module adapters 200, and/or of methods 300, according to the present disclosure. Elements that serve a similar, or at least substantially similar, purpose are labeled with like numbers in each of FIGS. 1-30, and these elements may not be discussed in detail herein with reference to each of FIGS. 1-30. Similarly, all elements may not be labeled in each of FIGS. 1-30, but reference numerals associated therewith may be utilized herein for consistency. Elements, components, and/or features that are discussed herein with reference to one or more of FIGS. 1-30 may be included in and/or utilized with any of FIGS. 1-30 without departing from the scope of the present disclosure.

In general, elements that are likely to be included in a particular embodiment are illustrated in solid lines, while elements that may be optional are illustrated in dashed lines. However, elements that are shown in solid lines may not be essential to all embodiments and, in some embodiments, may be omitted without departing from the scope of the present disclosure.

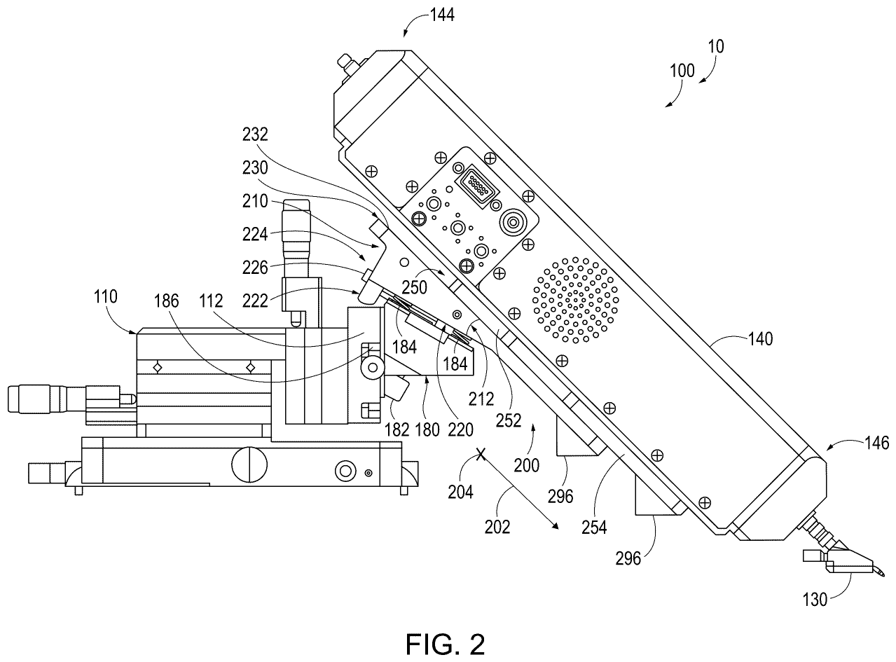

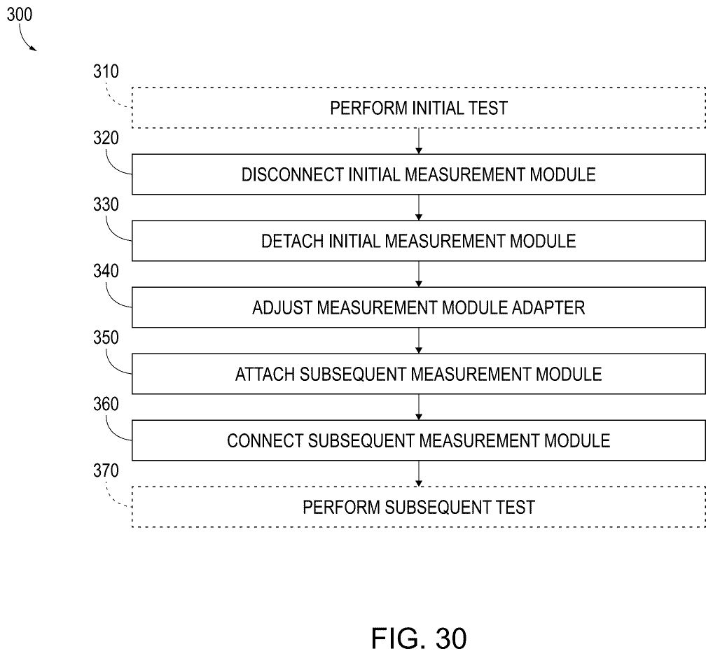

FIG. 1 is a schematic illustration of examples of probe systems 10 that include probe assemblies 100 that include measurement module adapters 200, according to the present disclosure. FIGS. 2-29 provide additional examples of components and/or structures of probe systems 10, probe assemblies 100, and/or measurement module adapters 200. FIG. 30 illustrates examples of methods of utilizing a probe system that include probe assemblies 100 that include measurement module adapters 200, according to the present disclosure.

As illustrated in FIG. 1, probe systems 10 may be configured to test a device under test (DUT) 92, which may be formed on, fabricated on, and/or supported by a substrate 90. Probe systems 10 include a chuck 20 that defines a support surface 22, which is configured to support substrate 90. Probe systems 10 also include a manipulator mounting surface 32, such as may be defined by a manipulator mounting plate 30, which also may be referred to herein as and/or may be a platen. Probe systems 10 also include probe assembly 100.

As discussed in more detail herein, probe assembly 100 includes a manipulator 110, measurement module adapter 200, a probe arm 120, a probe 130, and a measurement module 140. Manipulator 110 is operatively attached to manipulator mounting surface 32. Examples of manipulator 110 include a mechanical manipulator, a manually actuated manipulator, an electrically actuated manipulator, a rack and pinion assembly, a lead screw and nut assembly, a ball screw and nut assembly, a motor, a linear motor, a rotary motor, a stepper motor, a servo motor, and/or a piezoelectric actuator. Examples of probe arm 120 include a rigid, or at least substantially rigid, beam and/or fixture configured to support probe 130 relative to a remainder of probe assembly 100. Examples of probe 130 include an electrical probe and/or an optical probe.

Probe systems 10 also may include a signal generation and analysis assembly 40. The signal generation and analysis assembly may be configured to provide a test signal 42 to DUT 92 via measurement module 140 and/or via probe 130. Additionally or alternatively, the signal generation and analysis assembly may be configured to receive a resultant signal 44 from the DUT via the measurement module and/or via the probe. Examples of signal generation and analysis assembly 40 include a power source, an AC power source, a DC power source, a signal generator, a function generator, a signal analyzer, a spectrum analyzer, an electromagnetic radiation emitter, a waveform generator, an arbitrary waveform generator, and/or an electromagnetic radiation detector. Examples of test signal 42 include optical test signals and/or electrical test signals. Examples of resultant signal 44 include optical resultant signals and/or electrical resultant signals.

Chuck 20 may include any suitable structure that defines support surface 22 and/or that supports DUT 92. Examples of chuck 20 include a temperature-controlled chuck, a thermal chuck, a vacuum chuck, and/or an electrically shielded chuck.

DUT 92 may include any suitable structure that may be tested by probe systems 10. Examples of DUT 92 include an electronic device, an optoelectronic device, an optical device, a solid state device, and/or a semiconductor device. Similarly, substrate 90 may include any suitable structure upon which DUT 92 may be formed, fabricated and/or supported. Examples of substrate 90 include a wafer, a semiconductor wafer, a silicon wafer, and/or a Group Ill-V semiconductor wafer.

FIG. 1 illustrates probe system 10 with a single probe assembly 100. However, it is within the scope of the present disclosure that probe system 10 may include any suitable number of probe assemblies 100, such as may be utilized to provide, or to simultaneously provide, any suitable number of test signals 42 to DUT 92 and/or to receive, or to simultaneously receive, any suitable number of resultant signals 44 from the DUT. Similarly, FIG. 1 illustrates probe assembly 100 as including a single probe 130. However, it is within the scope of the present disclosure that probe assembly 100 may include any suitable number of probes 130.

During operation of probe systems 10, and as discussed in more detail herein, probe 130 may be operatively aligned with DUT 92, such as may be performed utilizing manipulator 110. Then, one or more test signals 42 may be provided to the DUT via one or more probes 130. Additionally or alternatively, one or more resultant signals 44 may be received from the DUT via the one or more probes.

As discussed, probe assemblies 100 include measurement module 140, and it may be desirable to utilize a given measurement module 140 for certain tests and/or with certain DUTs 92 and subsequently to utilize a different measurement module 140 for other tests and/or with other DUTs 92. With this in mind, measurement module adapter 200 is configured to be adjustable and/or to be configurable to a variety of different measurement modules 140. This is illustrated, for example, by the portions of probe assemblies 100 that are illustrated in FIGS. 2 and 4-6, each of which includes a different measurement module 140 that is mounted to the same measurement module adapter 200, with the measurement module adapter being differently configured for each measurement module 140.

Such a configuration may provide benefits over conventional probe systems that utilize different conventional fixtures for different measurement modules. As examples, an operator of probe systems 10 only may need to obtain a single measurement module adapter 200, and then the operator may utilize the single measurement module adapter for a variety of different measurement modules 140, thereby eliminating the time, costs, and/or space associated with fabricating, purchasing, dismounting, mounting, storing, and/or cataloging individual fixtures for each measurement module that might be utilized in the conventional probe system. As another example, and upon acquisition of a new and/or different measurement module, the operator of probe systems 10 need not expend the time and/or expense associated with fabricating and/or purchasing a corresponding fixture, which is unique to that measurement module, since the single measurement module adapter 200 simply may be configured to interface with the new and/or different measurement module.

As discussed, probe assemblies 100 include manipulator 110, measurement module adapter 200, probe arm 120, probe 130, and measurement module 140. Within probe assemblies 100, manipulator 110 is operatively attached to an adapter plate mount 222 of measurement module adapter 200, probe arm 120 is operatively attached to a probe arm mount 296 of the measurement module adapter and probe 130 is operatively attached to the probe arm. In addition, measurement module 140 is operatively attached to a bracket assembly 250 of measurement module adapter 200 via a plurality of insert fasteners 288.

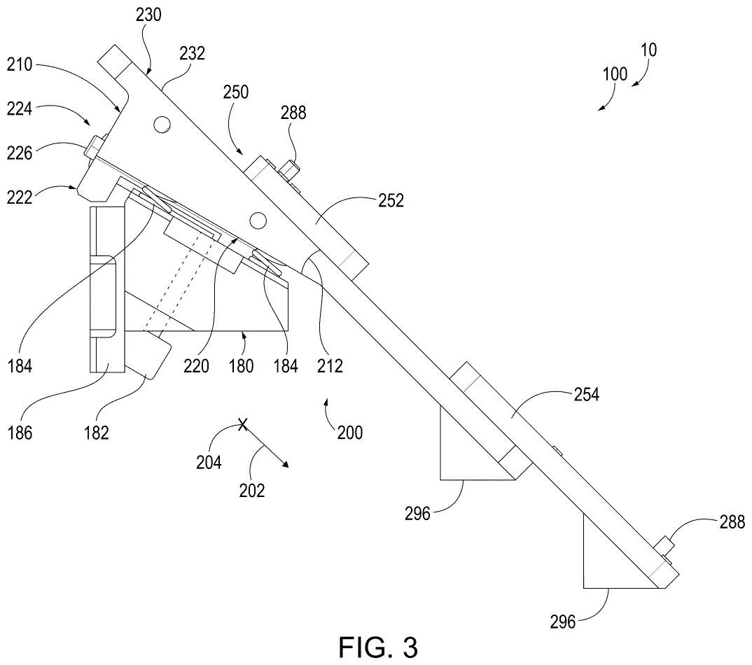

Manipulator 110 may be operatively attached to adapter plate mount 222 in any suitable manner, including direct or indirect operative attachment between the adapter plate mount and the manipulator. As an example, and as illustrated in dashed lines in FIG. 1 and in solid lines in FIGS. 2-3, probe assemblies 100 may include an intermediate mount 180, which may be configured to operatively attach manipulator 110 to adapter plate mount 222 of measurement module adapter 200.

In some such examples, intermediate mount 180 may be configured to pivotally mount to an adapter plate 210 of measurement module adapter 200 via adapter plate mount 222, such as to permit and/or facilitate rotation of probe 130 to permit, facilitate, and/or improve alignment between probe 130 and the DUT. In such examples, adapter plate 210 may be configured to pivot relative to intermediate mount 180 about an adapter plate mount fastener 226, which operatively attaches the intermediate mount to the adapter plate, and/or about a longitudinal axis of the adapter plate mount fastener. Adapter plate mount fastener 226 may be positioned and/or may extend within an adapter plate mount fastener-receiving region 224 of the adapter plate.

A Iso in such examples, intermediate mount 180 may include an adjustment screw 182 and one or more springs 184. Springs 184 may be configured to bias rotation of adapter plate 210 toward adjustment screw 182, and adjustment screw 182 may be configured to act against the bias provided by springs 184 to position and/or retain adapter plate 210 at a desired and/or target rotation relative to intermediate mount 180.

Also in some such examples, intermediate mount 180 may include and/or may be operatively attached to a dovetail plate 186. Dovetail plate 186 may be configured to be selectively received and/or retained within a dovetail plate recess 112 of manipulator 110. Such a configuration may permit and/or facilitate repeated attachment and separation of intermediate mount 180 and manipulator 110. This may include repeated attachment and/or separation while maintaining precise alignment between the intermediate mount and the manipulator during and/or subsequent to the attachment. Additionally or alternatively, such a configuration may permit and/or facilitate attachment of a plurality of different assemblies, which include intermediate mount 180, measurement module adapter 200, and measurement module 140, to a given manipulator 110.

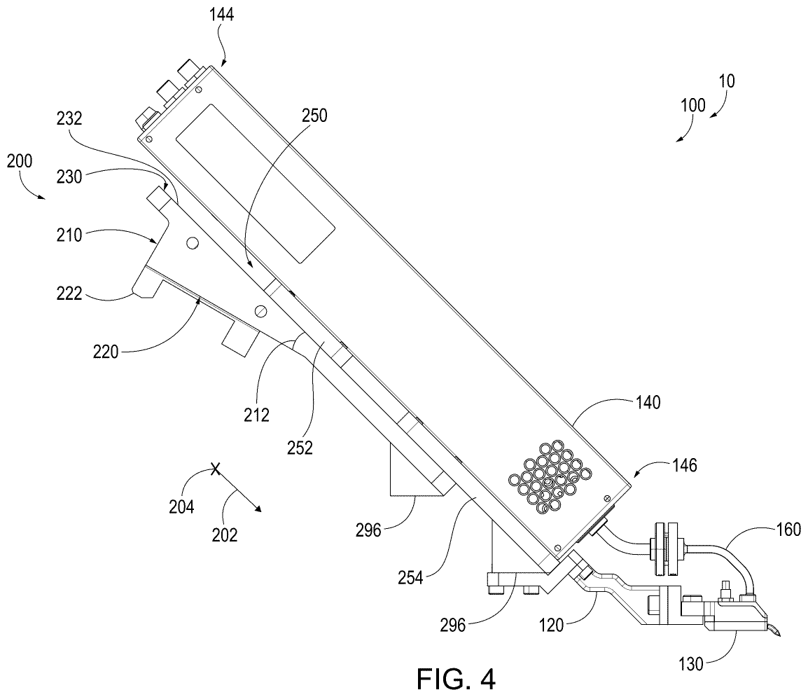

With continued reference to FIG. 1, and as also illustrated in FIGS. 4-8, probe assembly 100 may include a signal conduit 160. Signal conduit 160 may extend between measurement module 140 and probe 130 and/or may be configured to convey a signal 170 between the measurement module and the probe, as illustrated in FIG. 1. Examples of the signal include an electric signal, an electric current, a voltage, and/or an electromagnetic signal. Additional examples of the signal include test signal 42, resultant signal 44, and/or a signal that is modified by measurement module 140 but is based, at least in part, on the test signal and/or the resultant signal.

Measurement module 140 may include any suitable structure that may produce and/or receive signal 170, test signal 42, and/or resultant signal 44. Examples of measurement module 140 include a vector network analyzer frequency extender, a spectrum analyzer frequency extender, an rf source frequency extender, a noise parameter frequency extender, a load and source pull frequency extender, and/or a noise module.

As illustrated in FIG. 1, probe assembly 100 may include a plurality of measurement modules 140, such as a first 141 measurement module 140 and a second 142 measurement module 140. In such a configuration, first 141 measurement module 140 and second 142 measurement module 140 both may be operatively attached to probe assembly 100, such as via measurement module adapter 200 and/or bracket assembly 250 thereof. Also in such a configuration, probe assembly 100 may include a plurality of signal conduits 160, including a first signal conduit 171 extending from the first measurement module to the probe, and a second signal conduit 172 extending from the second measurement module to the first measurement module and/or to the probe.

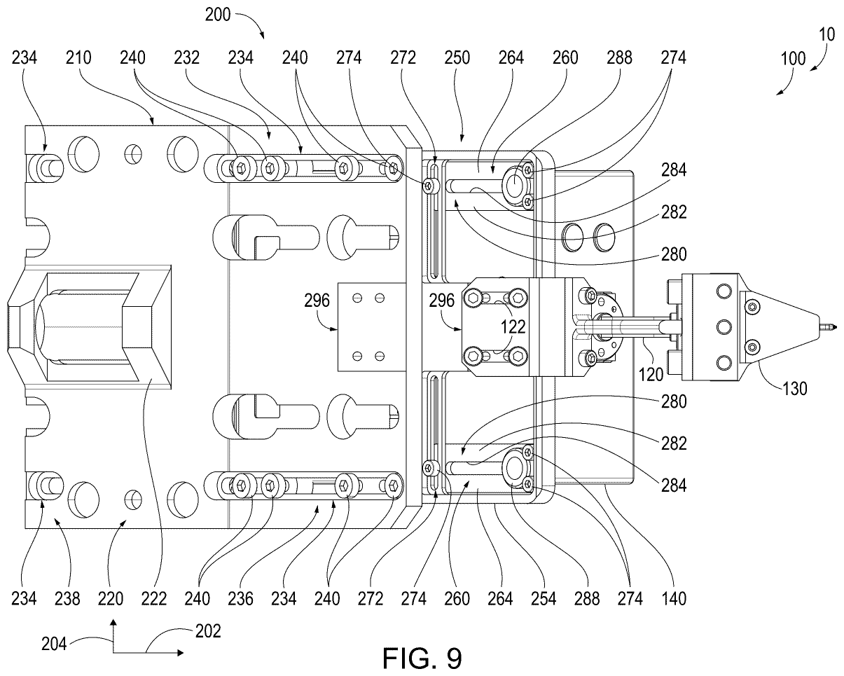

It is within the scope of the present disclosure that probe assembly 100 and/or measurement module adapter 200 thereof may include a plurality of separate, distinct, and/or spaced apart probe arm mounts 296 and/or that probe arm mounts 296 may be configured to permit and/or facilitate operative attachment of probe arm 120 at a plurality of different relative orientations with respect to a remainder of the probe assembly and/or of the measurement module adapter, as illustrated in FIGS. 1-6, 9-10, 12, and 14. Additionally or alternatively, and as illustrated in FIGS. 9 and 13-14, probe arm 120 may include probe arm mounting slots 122, which may facilitate at least a subset of the plurality of different relative orientations. Additionally or alternatively, probe arm mounts 296 may define corresponding slots that facilitate at least a subset of the plurality of relative orientations.

Such a configuration may permit and/or facilitate accommodation of differing heights and/or sizes of measurement modules 140 and/or may facilitate connection of signal conduit 160 between the measurement module and the probe for the differing heights and/or sizes of the measurement module.

As discussed, measurement module adapters 200 are configured to operatively attach measurement module 140 and/or probe arm 120 to manipulator 110 of probe system 10, as illustrated in FIG. 1. Measurement module adapters 200 include an adapter plate 210, a bracket assembly 250, a plurality of inserts 280, and a probe arm mount 296, as collectively illustrated by FIGS. 1-29. Adapter plate 210 includes and/or defines a manipulator-facing surface 220 that defines an adapter plate mount 222 configured to be directly or indirectly and operatively attached to manipulator 110 of probe assembly 100 and/or of probe system 10, as discussed in more detail herein and collectively illustrated by FIGS. 1-7, 9-10, and 12-18. Adapter plate 210 also includes and/or defines a module-facing surface 230 that defines a bracket assembly mount 232, as collectively illustrated by FIGS. 1-8, 10-13, and 15-18.

Bracket assembly 250 is selectively and operatively affixed to bracket assembly mount 232 and includes a plurality of insert-receiving regions 260, as collectively illustrated by FIGS. 1, 7-9, 11, 14, 19, 21-23, and 25-26. Measurement module adapter 200 is configured to permit and/or facilitate selective adjustment of a relative orientation between bracket assembly 250 and adapter plate 210 along a first adjustment axis 202, such as via and/or utilizing bracket assembly mount 232, as collectively illustrated by FIGS. 1-14 and discussed in more detail herein.

Each insert 280 is selectively and operatively attached to bracket assembly 250 within a corresponding insert-receiving region 260, as collectively illustrated by FIGS. 1, 7-9, 11, and 13-14. As an example, each insert 280 may be selectively and operatively attached to the corresponding insert-receiving region via a corresponding plurality of insert-receiving region fasteners 274, as collectively illustrated by FIGS. 1, 9, and 13-14. In addition, each insert 280 includes a corresponding insert fastener 288, which is configured to be operatively attached to measurement module 140 and/or to operatively attach the measurement module to the bracket assembly, as collectively illustrated by FIGS. 1, 3, 9-11, and 13. Each insert 280 and the corresponding insert-receiving region together are configured to permit and/or facilitate adjustment of a relative orientation between the corresponding insert fastener 288 and bracket assembly 250 along a second adjustment axis 204, as collectively illustrated by FIGS. 1-14. The second adjustment axis may extend perpendicular, or at least substantially perpendicular, to the first adjustment axis.

Adapter plate 210 may include any suitable structure that is adapted, configured, sized, and/or constructed to be operatively attached to manipulator 110, to measurement module 140, and/or to probe arm 120. Additionally or alternatively, adapter plate 210 may include any suitable structure that is adapted, configured, sized, and/or constructed to include and/or define manipulator-facing surface 220, adapter plate mount 222, module-facing surface 230, and/or bracket assembly mount 232.

Manipulator-facing surface 220 and/or adapter plate mount 222 may at least partially form and/or define an adapter plate mount plane, and module-facing surface 230 may at least partially form and/or define a module-facing surface plane. The adapter plate mount plane may extend and/or may be oriented at an angle 212 with respect to and/or relative to the module-facing surface plane, as collectively illustrated by FIGS. 1-6, 10, 12, and 16. Additionally or alternatively, angle 212 may extend and/or may be defined between module-facing surface 230 and the elongate axis of adapter plate mount fastener 226. Examples of angle 212 include at least 10 degrees, at least 15 degrees, at least 20 degrees, at least 25 degrees, at least 30 degrees, at least 35 degrees, at least 40 degrees, at least 45 degrees, at least 50 degrees, at most 80 degrees, at most 75 degrees, at most 70 degrees, at most 65 degrees, at most 60 degrees, at most 55 degrees, at most 50 degrees, at most 45 degrees, and/or at most 40 degrees.

As illustrated, first adjustment axis 202 may extend parallel, or at least substantially parallel, to module-facing surface 230 and/or to the module-facing surface plane. Additionally or alternatively, second adjustment axis 204 may extend parallel, or at least substantially parallel, to the module-facing surface and/or to the module-facing surface plane. Stated differently, measurement module adapter 200 may be configured to permit and/or facilitate adjustment of a relative orientation among insert fasteners 288 within, or only within, a plane that extends parallel, or at least substantially parallel, to the module-facing surface plane.

Adapter plate 210 may be a unitary, a monolithic, and/or a single-piece adapter plate. Stated differently, adapter plate 210 may be a unitary, monolithic, and/or single-piece structure that defines manipulator-facing surface 220, adapter plate mount 222, module-facing surface 230, bracket assembly mount 232, and/or probe arm mount 296.

Manipulator-facing surface 220 may include any suitable structure that may define, or at least partially define, adapter plate mount 222 and/or that is configured to be operatively attached to manipulator 110. Adapter plate mount 222 may be a fixed adapter plate mount and/or may be configured to be operatively attached to a single, or to a specific, manipulator 110 and/or intermediate mount 180. Stated differently, and in contrast with bracket assembly 250, adapter plate mount 222 may define a fixed orientation with respect to a remainder of adapter plate 210 and/or may define a fixed adapter plate mounting configuration, which may be based, at least in part, on a geometry and/or an identity of the manipulator and/or of the intermediate mount.

In some examples of measurement module adapters 200, probe arm mount 296 may be defined by and/or on adapter plate 210. As examples, the probe arm mount may extend from and/or may be defined on manipulator-facing surface 220 of the adapter plate, as collectively illustrated by FIGS. 1-6, 9-10, 12, 14, 16, and 18. Additionally or alternatively, and in some examples, probe arm mount 296 may be defined by and/or on bracket assembly 250, as collectively illustrated by FIGS. 1-7, 9-10, 12, 14, and 19-21.

Module-facing surface 230 may include any suitable structure that defines bracket assembly mount 232. As an example, module-facing surface 230 may include and/or be a planar, an at least partially planar, and/or an at least substantially planar module-facing surface.

Similarly, bracket assembly mount 232 may include and/or be any suitable structure that may be configured to be operatively affixed to bracket assembly 250 and/or to permit and/or facilitate adjustment of the relative orientation between the bracket assembly and the adapter plate along the first adjustment axis and/or along the second adjustment axis. An example of bracket assembly mount 232 includes an elongate slot 234, which may extend along the first adjustment axis and/or along the second adjustment axis, as collectively illustrated by FIGS. 1, 7-9, 11, 13-15, and 17-18. An example of the elongate slot includes an elongate T-slot.

In some examples, bracket assembly mount 232 may include a pair 236 of elongate slots 234, as collectively illustrated by FIGS. 1, 7, 9, 11, 13-15, and 17-18. The pair of elongate slots may extend parallel, or at least substantially parallel, to one another, to the first adjustment axis, and/or to the second adjustment axis. The pair of elongate slots may be spaced apart from one another, such as along second adjustment axis 204 and/or may extend along corresponding sides of module-facing surface 230. Such a configuration may increase a rigidity of operative attachment between the bracket assembly and the adapter plate.

In some examples, the pair 236 of elongate slots 234 may include and/or be a first pair 236 of elongate slots 234, and bracket assembly mount 232 also may include a second pair 238 of elongate slots 234, as collectively illustrated by FIGS. 1, 7-9, 11, 13-15, and 17-18. The second pair of elongate slots may extend parallel, or at least substantially parallel, to one another, to the first adjustment axis, and/or to the second adjustment axis. The second pair of elongate slots may be spaced apart from one another, such as along the second adjustment axis and/or may extend along corresponding sides of module-facing surface 230. The second pair of elongate slots may be spaced apart from the first pair of elongate slots along the first adjustment axis. Bracket assembly 250 may be selectively and operatively affixed to the bracket assembly mount via both the first pair of elongate slots and the second pair of elongate slots. Such a configuration may facilitate attachment of relatively longer measurement modules 140 to measurement module adapter 200 and/or may facilitate attachment of a plurality of measurement modules to the measurement module adapter.

Bracket assembly mount 232 may include a plurality of bracket assembly mount fasteners 240, which may be configured to operatively attach bracket assembly 250 to adapter plate 210, as collectively illustrated by FIGS. 1, 9, and 12-14. Each bracket assembly mount fastener 240 may extend between adapter plate 210 and bracket assembly 250, may be affixed to the bracket assembly, may be affixed to the adapter plate, and/or may be positioned at least partially within a corresponding elongate slot 234 of the adapter plate. In such a configuration, bracket assembly mount fasteners 240 may be configured to be loosened to permit and/or facilitate adjustment of the relative orientation between the bracket assembly and the adapter plate, such as along the first adjustment axis. Additionally or alternatively, bracket assembly mount fasteners 240 may be configured to be tightened to resist the adjustment and/or to retain the bracket assembly at a desired orientation with respect to the adapter plate.

It is within the scope of the present disclosure that bracket assembly mount 232 may be configured to permit adjustment of the relative orientation between at least one component of bracket assembly 250 and adapter plate 210 through a first adjustment axis range-of-motion. Examples of the first adjustment axis range-of-motion include at least 100 millimeters (mm), at least 125 mm, at least 150 mm, at least 175 mm, at least 200 mm, at most 400 mm, at most 375 mm, at most 350 mm, at most 325 mm, at most 300 mm, at most 275 mm, at most 250 mm, at most 225 mm, and/or at most 200 mm.

Bracket assembly 250 may include any suitable structure that may be adapted, configured, designed, sized, and/or constructed to be operatively affixed to bracket assembly mount 232 and/or to include insert-receiving regions 260. In some examples of measurement module adapters 200, and as discussed, probe arm mount 296 may be at least partially, or even completely, defined by bracket assembly 250 and/or by at least one component of the bracket assembly.

As illustrated in dashed lines in FIG. 1 and in solid lines in FIGS. 2-8, 10-14, and 23-26, bracket assembly 250 may include a probe-distal bracket 252, which may be configured to be operatively attached to bracket assembly mount 232. In such a configuration, measurement module adapter 200, bracket assembly mount 232, and/or probe-distal bracket 252 may be configured to permit and/or facilitate adjustment of a relative orientation between the probe-distal bracket and the adapter plate along first adjustment axis 202. In some examples, probe-distal bracket 252 may be configured to be operatively attached to a probe-distal end region 144 of measurement module 140 and/or relatively proximate the probe-distal end region. Alternatively, and when probe assembly 100 includes both first 141 measurement module 140 and second 142 measurement module 140, probe-distal bracket 252 may be configured to be operatively attached to the second measurement module.

Probe-distal bracket 252 may include a pair of probe-distal 262 insert-receiving regions 260, as collectively illustrated by FIGS. 1, 7-8, 11, 13, 23, and 25-26. In addition, corresponding inserts 280 may be selectively and operatively attached to bracket assembly 250 at and/or within each probe-distal insert-receiving region. Such a configuration may permit selective and operative attachment of probe-distal bracket 252 to measurement module 140.

As illustrated in dashed lines in FIG. 1 and in solid lines in FIGS. 2-14 and 19-22, bracket assembly 250 may include a probe-proximate bracket 254, which may be configured to be operatively attached to bracket assembly mount 232. In such a configuration, measurement module adapter 200, bracket assembly mount 232, and/or probe-proximate bracket 254 may be configured to permit and/or facilitate adjustment of a relative orientation between the probe-proximate bracket and the adapter plate along first adjustment axis 202. Probe-proximate bracket 254 may be configured to be operatively attached to a probe-proximate end region 146 of measurement module 140, or to first 141 measurement module 140.

Probe-proximate bracket 254 may include a pair of probe-proximate 264 insert-receiving regions 260, as collectively illustrated by FIGS. 1, 7-9, 11, 13-14, 19, and 21-22. In addition, corresponding inserts 280 may be selectively and operatively attached to bracket assembly 250 at and/or within each probe-proximate insert-receiving region. Such a configuration may permit selective and operative attachment of probe-proximate bracket 254 to measurement module 140. In some examples, and as illustrated, probe arm mount 296 may be at least partially or even completely defined by probe-proximate bracket 254.

As illustrated in dashed lines in FIG. 1, bracket assembly 250 may include an intermediate bracket 256, which may be configured to be operatively attached to bracket assembly mount 232. In such a configuration, measurement module adapter 200, bracket assembly mount 232, and/or intermediate bracket 256 may be configured to permit and/or facilitate adjustment of a relative orientation between the intermediate bracket and the adapter plate along first adjustment axis 202.

Intermediate bracket 256 may be configured to be operatively attached to probe-distal end region 144 of first 141 measurement module 140. In addition, probe-distal bracket 252 may be configured to be operatively attached to a second 142 measurement module 140, which may be separate, distinct, and/or spaced apart from first 141 measurement module 140.

Intermediate bracket 256 may include a pair of intermediate 266 insert-receiving regions 260. In addition, corresponding inserts 280 may be selectively and operatively attached to bracket assembly 250 at and/or within each intermediate insert-receiving region. Such a configuration may permit selective and operative attachment of intermediate bracket 256 to measurement modules 140.

It is within the scope of the present disclosure that measurement module adaptors 200 and/or adapter plates 210 thereof may be configured to permit and/or facilitate independent motion of probe-distal bracket 252, probe-proximate bracket 254, and/or intermediate bracket 256 along first adjustment axis 202. As an example, the measurement module adapter may be configured to permit independent adjustment of the relative orientation between the probe-distal bracket and the adapter plate along the first adjustment axis and of the relative orientation between the probe-proximate bracket and the adapter plate along the first adjustment axis.

Insert-receiving regions 260 may include any suitable structure that may be adapted, configured, designed, sized, and/or constructed to receive and/or to be operatively attached to corresponding inserts 280. As indicated at 268 in FIGS. 1, 11, and 13, at least a subset of insert-receiving regions 260 may be sized to receive corresponding insert 280 at a single, or at only a single, relative orientation. Stated differently, such insert-receiving regions may be only slightly larger than the corresponding insert, such as to provide clearance for insertion of the corresponding insert, and/or may be configured such that the corresponding insert is operatively attached to the bracket assembly within the insert-receiving region at only a single, or a specific, relative orientation.

Additionally or alternatively, and as indicated at 270 in FIGS. 1, 11, and 13, at least a subset of insert-receiving regions 260 may be oversized with respect to the corresponding insert. In such a configuration, the insert-receiving region may be sized to receive the corresponding insert in a plurality of different, or in a range of, relative orientations along the first adjustment axis and/or along the second adjustment axis. As an example, the subset of the plurality of insert-receiving regions may include an insert attachment channel 272, a plurality of insert attachment channels 272, and/or a pair of opposed insert attachment channels 272. Insert attachment channels 272 may be configured to facilitate selective attachment of the corresponding insert at a plurality of spaced apart locations along the length of the insert attachment channel, thereby permitting and/or facilitating the plurality of different, or a range of, relative orientations for the corresponding insert with respect to a remainder of the bracket assembly. Insert attachment channels 272 associated with a given insert-receiving region 260 may extend parallel, or at least substantially parallel, to first adjustment axis 202 or to second adjustment axis 204, thereby permitting and/or facilitating the range of relative orientations along the corresponding adjustment axis.

Stated differently, at least a subset of insert-receiving regions 260 may be configured to permit selective translation of the corresponding insert therein, along the first adjustment axis, and/or along the second adjustment axis. This may include selective translation through an insert range-of-motion. Examples of the insert range-of-motion include at least 20 mm, at least 30 mm, at least 40 mm, at least 50 mm, at least 60 mm, at least 70 mm, at least 80 mm, at least 90 mm, at most 150 mm, at most 140 mm, at most 130 mm, at most 120 mm, at most 110 mm, at most 100 mm, at most 90 mm, and/or at most 80 mm.

Inserts 280 may include any suitable structure that is configured to be selectively and operatively attached to and/or received within corresponding insert-receiving regions 260, such as via corresponding insert-receiving region fasteners 274. At least a subset of inserts 280 may include an insert base 282 that defines an insert opening 284, as indicated in FIGS. 1, 9, 11, and 27-29. Insert base 282 may be sized to be received within the corresponding insert-receiving region 260, and the corresponding insert fastener 288 may be received within insert opening 284. Insert opening 284 may include and/or be an insert slot, which may be sized to permit translation of the corresponding insert fastener 288 relative to the insert base, such as along the first adjustment axis or the second adjustment axis. In some examples, the insert slot may include and/or be an insert T-slot.

When present, insert opening 284 in the form of the insert fastener slot may be sized to permit translation of the corresponding insert fastener 288 through an insert fastener range of motion. Examples of the insert fastener range of motion include at least 20 mm, at least 30 mm, at least 40 mm, at least 50 mm, at least 60 mm, at least 70 mm, at least 80 mm, at least 90 mm, at most 150 mm, at most 140 mm, at most 130 mm, at most 120 mm, at most 110 mm, at most 100 mm, at most 90 mm, and/or at most 80 mm.

Insert fasteners 288 may include any suitable structure that may be operatively attached to insert base 282, that may be received within insert opening 284, that may translate relative to the insert base along the insert fastener slot, that may be configured to be selectively and operatively attached to the measurement module, and/or that may be configured to selectively and operatively attach the measurement module to the bracket assembly. Measurement module 140 may include a plurality of corresponding module fastening regions 148, as illustrated in FIG. 1, that may be configured to receive, to be received by, to interface with, and/or to threadingly engage with insert fasteners 288.

A plurality of types of fasteners are disclosed herein, including adapter plate mount fastener 226, bracket assembly mount fasteners 240, insert-receiving region fasteners 274, and insert fasteners 288. Each of these fasteners may be configured to selectively and operatively attach corresponding structures to one another. Each of these fasteners additionally or alternatively may be configured to selectively and operatively facilitate detachment of the corresponding structures from one another. Each of these fasteners additionally or alternatively may be configured for repeated attachment and detachment of the corresponding structures without damage to the fasteners and/or without damage to the corresponding structures. Examples of adapter plate mount fastener 226, bracket assembly mount fasteners 240, insert-receiving region fasteners 274, and/or insert fasteners 288 include male fasteners, female fasteners, threaded fasteners, bolts, screws, and/or nuts.

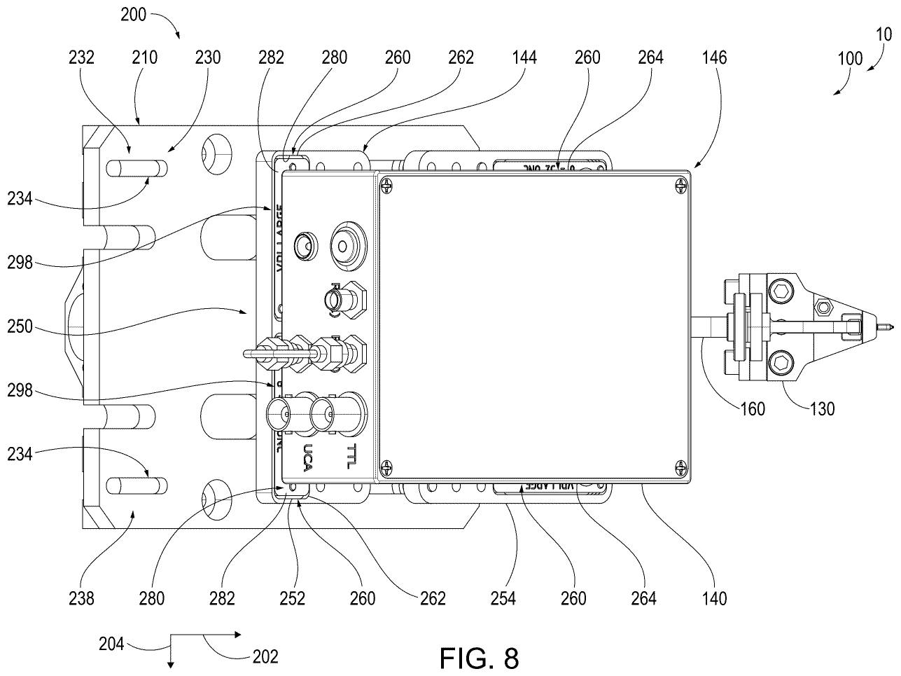

As illustrated in dashed lines in FIG. 1 and in solid lines in FIGS. 8, 11, 13-14, 21, and 27-28, measurement module adapters 200 may include visual indicia 298. Visual indicia 298 may be included to speed and/or facilitate attachment of a given measurement module 140 to manipulator 110 utilizing measurement module adapters 200. As examples, visual indicia 298 may be indicative of, or may indicate to the operator of the probe system, a size of the corresponding insert fastener, a thread pitch of the corresponding insert fastener, an identity of a measurement module to which the corresponding insert fastener is configured to operatively attach, a desired position for the corresponding insert fastener for attachment to the measurement module, a desired position for the corresponding insert base for attachment to the measurement module, and/or a location of one or more components of the bracket assembly with respect to the adapter plate.

Visual indicia 298 may be present on, may be defined by, may be formed on, may be associated with, and/or may be attached to any suitable structure and/or structures of the measurement module adapters. As examples, visual indicia 298 may be present on adapter plate 210, bracket assembly 250, probe-distal bracket 252, probe-proximate bracket 254, intermediate bracket 256, insert-receiving regions 260, and/or inserts 280.

As discussed, measurement module adapters 200 may be configured and/or utilized to attach a plurality of distinct measurement modules 140 to manipulator 110. The distinct measurement modules may be configured to operatively attach to different fasteners, to different size fasteners, to different length fasteners, to fasteners of differing diameters, to fasteners of differing thread pitches, and/or to differing styles of fasteners. With this in mind, measurement module adapters 200 may include a plurality of different and/or distinct inserts 280, such as may be configured to operatively attach to the distinct measurement modules.

In a specific example, the plurality of inserts 280 of measurement module adapters 200 may include a first set of inserts, which may be configured to be operatively attached to a first measurement module 141. In addition, measurement module adapters 200 may include a plurality of sets of inserts, with each set of inserts being configured to be operatively attached to a corresponding measurement module of the plurality of distinct measurement modules. At least one insert in each set of inserts may differ from at least one insert in each other set of inserts. As examples, the at least one insert may have a different insert fastener when compared to the at least one other insert. Visual indicia 298 also may differ among the plurality of sets of inserts.

FIG. 30 is a flowchart depicting examples of methods 300 of utilizing a probe system, according to the present disclosure. Methods 300 may include performing an initial test at 310, and methods 300 include disconnecting an initial measurement module at 320 and detaching the initial measurement module at 330. Methods 300 also include adjusting a measurement module adapter at 340, attaching a subsequent measurement module at 350, and connecting the subsequent measurement module at 360. Methods 300 further may include performing a subsequent test at 370.

Performing the initial test at 310 may include performing the initial test on an initial device under test with, via, and/or utilizing the probe system. The performing at 310 may be performed in any suitable manner and/or may include any suitable initial test. As examples, the performing at 310 may include aligning a probe of the probe system with the device under test, providing a test signal to the device under test, and/or receiving a resultant signal from the device under test. Stated differently, the performing at 310 may include transferring one or more signals between the probe and the device under test. The providing the test signal and/or the receiving the resultant signal may be performed via and/or utilizing the probe and/or the measurement module. Examples of the test signal, the resultant signal, and the signal are disclosed herein with reference to test signal 42, resultant signal 44, and signal 170, respectively.

The performing at 310 may be performed with any suitable timing and/or sequence during methods 300. As examples, the performing at 310 may be performed prior to the disconnecting at 320, the detaching at 330, the adjusting at 340, the attaching at 350, the connecting at 360, and/or the performing at 370.

Disconnecting the initial measurement module at 320 may include disconnecting the initial measurement module from the probe of the probe system. This may include disconnection of an initial signal conduit from the initial measurement module and/or from the probe. The initial signal conduit may be utilized to convey the signal, the test signal, and/or the resultant signal during the performing at 310. Examples of the initial signal conduit are disclosed herein with reference to signal conduit 160. Examples of the measurement module are disclosed herein with reference to measurement module 140. Examples of the probe are disclosed herein with reference to probe 130.

The disconnecting at 320 may be performed with any suitable timing and/or sequence during methods 300. As examples, the disconnecting at 320 may be performed subsequent to the performing at 310 and/or the detaching at 330. As additional examples, the disconnecting at 320 may be performed at least partially concurrently with the detaching at 330 and/or with the adjusting at 340. As further examples, the disconnecting at 320 may be performed prior to the detaching at 330, the adjusting at 340, the attaching at 350, the connecting at 360, and/or the performing at 370.

Detaching the initial measurement module at 330 may include detaching the initial measurement module from the measurement module adapter of the probe system. This may include disengaging an initial plurality of insert fasteners of the measurement module adapter from the measurement module. Examples of the measurement module adapter are disclosed herein with reference to measurement module adapter 200. Examples of the initial plurality of insert fasteners are disclosed herein with reference to insert fasteners 288.

The detaching at 330 may be performed with any suitable timing and/or sequence during methods 300. As examples, the detaching at 330 may be performed subsequent to the performing at 310 and/or the disconnecting at 320. As additional examples, the detaching at 330 may be performed at least partially concurrently with the disconnecting at 320 and/or with the adjusting at 340. As further examples, the detaching at 330 may be performed prior to the adjusting at 340, the attaching at 350, the connecting at 360, and/or the performing at 370.

Adjusting the measurement module adapter at 340 may include adjusting the measurement module adapter to interface with the subsequent measurement module. The subsequent measurement module may differ from the initial measurement module, and the adjusting at 340 may be performed in any suitable manner. As an example, the adjusting at 340 may include utilizing at least one visual indicia of the measurement module adapter to facilitate and/or to guide adjustment. Examples of the visual indicia are disclosed herein with reference to visual indicia 298.

As another example, the adjusting at 340 may include operatively translating at least one insert fastener of the initial plurality of insert fasteners relative to at least one other insert fastener of the initial plurality of insert fasteners. This may include operative translation of the at least one insert fastener within a plane that is parallel to a bracket assembly mount of the measurement module adapter. In some examples, the operatively translating may include operatively translating at least one insert of the measurement module adapter, which includes the at least one insert fastener, within a corresponding insert-receiving region of the measurement module adapter. In some examples, the operatively translating may include operatively translating the at least one fastener within an insert fastener slot of the insert and/or of at least one insert base of the insert. In some examples, the operatively translating may include operatively translating a probe-distal bracket, a probe-proximate bracket, and/or an intermediate bracket of the measurement module adapter relative to an adapter plate of the measurement module adapter. Such translation may be along a first adjustment axis and/or along a second adjustment axis.

Examples of the bracket assembly mount are disclosed herein with reference to bracket assembly mounts 232. Examples of the at least one insert are disclosed herein with reference to inserts 280. Examples of the at least one insert-receiving region are disclosed herein with reference to insert-receiving regions 260. Examples of the insert fastener slot are disclosed herein with reference to insert opening 284. Examples of the probe-distal bracket, the probe-proximate bracket, and the intermediate bracket are disclosed herein with reference to probe-distal bracket 252, probe-proximate bracket 254, and intermediate bracket 256, respectively. Examples of the first adjustment axis and the second adjustment axis are disclosed herein with reference to first adjustment axis 202 and second adjustment axis 204, respectively.

As another example, the adjusting at 340 may include replacing at least one insert of the measurement module adapter with a structurally different insert of the measurement module adapter. This may include selecting the structurally different insert from a plurality of inserts of the measurement module adapter and may include utilizing at least one visual indicia of the structurally different insert, such as to identify the structurally different insert and/or to establish that the structurally different insert is configured to be selectively and operatively attached to the subsequent measurement module.

The adjusting at 340 may be performed with any suitable timing and/or sequence during methods 300. As examples, the adjusting at 340 may be performed subsequent to the performing at 310, the disconnecting at 320, and/or the detaching at 330. As additional examples, the adjusting at 340 may be performed at least partially concurrently with the disconnecting at 320, with the detaching at 330, and/or with the attaching at 350. As further examples, the adjusting at 340 may be performed prior to the attaching at 350, the connecting at 360, and/or the performing at 370.

Attaching the subsequent measurement module at 350 may include attaching the subsequent measurement module to the measurement module adapter via engagement of a subsequent plurality of insert fasteners of the measurement module adapter with the subsequent measurement module. Examples of the subsequent plurality of insert fasteners are disclosed herein with reference to insert fasteners 288.

In some examples, such as when the adjusting at 340 includes replacing the at least one insert, the initial plurality of insert fasteners may differ from the subsequent plurality of insert fasteners. In some examples, such as when the adjusting at 340 includes operatively translating the at least one insert fastener and/or when the adjusting at 340 does not include the replacing the at least one insert, the initial plurality of insert fasteners and the subsequent plurality of insert fasteners may include and/or be the same insert fasteners, or the same plurality of insert fasteners.

The attaching at 350 may be performed with any suitable timing and/or sequence during methods 300. As examples, the attaching at 350 may be performed subsequent to the performing at 310, the disconnecting at 320, the detaching at 330, and/or the adjusting at 340. As additional examples, the attaching at 350 may be performed at least partially concurrently with the adjusting at 340. As further examples, the attaching at 350 may be performed prior to the connecting at 360 and/or the performing at 370.

Connecting the subsequent measurement module at 360 may include connecting the subsequent measurement module to the probe, or to a different probe, via a subsequent signal conduit. Examples of the subsequent signal conduit are disclosed herein with reference to signal conduit 160. In some examples, the initial signal conduit may differ from the subsequent signal conduit. In some examples, the initial signal conduit and the subsequent signal conduit may include and/or be the same signal conduit.

The connecting at 360 may be performed with any suitable timing and/or sequence during methods 300. As examples, the connecting at 360 may be performed subsequent to the performing at 310, the disconnecting at 320, the detaching at 330, the adjusting at 340, and/or the attaching at 350. As additional examples, the connecting at 360 may be performed at least partially concurrently with the adjusting at 340 and/or with the attaching at 350. As further examples, the connecting at 360 may be performed prior to the performing at 370.

Performing the subsequent test at 370 may include performing the subsequent test on a subsequent device under test with, via, and/or utilizing the probe system. The performing at 370 may be performed in any suitable manner, may include any suitable subsequent test, and/or may be at least substantially similar to the performing at 310 with the exception that the subsequent test is performed utilizing the subsequent measurement module. In general, the subsequent test differs from the initial test.

In some examples, the subsequent device under test may differ from the initial device under test, such as when the disconnecting at 320, the detaching at 330, the adjusting at 340, the attaching at 350, and/or the connecting at 360 are performed to transition the probe system from testing a first configuration of the initial device under test to testing a second configuration of the subsequent device under test. In some examples, the first device under test and the second device under test may be the same device under test, such as when the disconnecting at 320, the detaching at 330, the adjusting at 340, the attaching at 350, and/or the connecting at 360 are performed to transition the probe system from performing the initial test to performing the subsequent test on the same device under test.

The performing at 370 may be performed with any suitable timing and/or sequence during methods 300. As examples, the performing at 370 may be performed subsequent to the performing at 310, the disconnecting at 320, the detaching at 330, the adjusting at 340, the attaching at 350, and/or the connecting at 360.

In the present disclosure, several of the illustrative, non-exclusive examples have been discussed and/or presented in the context of flow diagrams, or flow charts, in which the methods are shown and described as a series of blocks, or steps. Unless specifically set forth in the accompanying description, it is within the scope of the present disclosure that the order of the blocks may vary from the illustrated order in the flow diagram, including with two or more of the blocks (or steps) occurring in a different order and/or concurrently.

As used herein, the term “and/or” placed between a first entity and a second entity means one of (1) the first entity, (2) the second entity, and (3) the first entity and the second entity. Multiple entities listed with “and/or” should be construed in the same manner, i.e., “one or more” of the entities so conjoined. Other entities may optionally be present other than the entities specifically identified by the “and/or” clause, whether related or unrelated to those entities specifically identified. Thus, as a non-limiting example, a reference to “A and/or B,” when used in conjunction with open-ended language such as “comprising” may refer, in one embodiment, to A only (optionally including entities other than B); in another embodiment, to B only (optionally including entities other than A); in yet another embodiment, to both A and B (optionally including other entities). These entities may refer to elements, actions, structures, steps, operations, values, and the like.

As used herein, the phrase “at least one,” in reference to a list of one or more entities should be understood to mean at least one entity selected from any one or more of the entities in the list of entities, but not necessarily including at least one of each and every entity specifically listed within the list of entities and not excluding any combinations of entities in the list of entities. This definition also allows that entities may optionally be present other than the entities specifically identified within the list of entities to which the phrase “at least one” refers, whether related or unrelated to those entities specifically identified. Thus, as a non-limiting example, “at least one of A and B” (or, equivalently, “at least one of A or B,” or, equivalently “at least one of A and/or B”) may refer, in one embodiment, to at least one, optionally including more than one, A, with no B present (and optionally including entities other than B); in another embodiment, to at least one, optionally including more than one, B, with no A present (and optionally including entities other than A); in yet another embodiment, to at least one, optionally including more than one, A, and at least one, optionally including more than one, B (and optionally including other entities). In other words, the phrases “at least one,” “one or more,” and “and/or” are open-ended expressions that are both conjunctive and disjunctive in operation. For example, each of the expressions “at least one of A, B, and C,” “at least one of A, B, or C,” “one or more of A, B, and C,” “one or more of A, B, or C,” and “A, B, and/or C” may mean A alone, B alone, C alone, A and B together, A and C together, B and C together, A, B, and C together, and optionally any of the above in combination with at least one other entity.

In the event that any patents, patent applications, or other references are incorporated by reference herein and (1) define a term in a manner that is inconsistent with and/or (2) are otherwise inconsistent with, either the non-incorporated portion of the present disclosure or any of the other incorporated references, the non-incorporated portion of the present disclosure shall control, and the term or incorporated disclosure therein shall only control with respect to the reference in which the term is defined and/or the incorporated disclosure was present originally.

As used herein the terms “adapted” and “configured” mean that the element, component, or other subject matter is designed and/or intended to perform a given function. Thus, the use of the terms “adapted” and “configured” should not be construed to mean that a given element, component, or other subject matter is simply “capable of” performing a given function but that the element, component, and/or other subject matter is specifically selected, created, implemented, utilized, programmed, and/or designed for the purpose of performing the function. It is also within the scope of the present disclosure that elements, components, and/or other recited subject matter that is recited as being adapted to perform a particular function may additionally or alternatively be described as being configured to perform that function, and vice versa.

As used herein, the phrase, “for example,” the phrase, “as an example,” and/or simply the term “example,” when used with reference to one or more components, features, details, structures, embodiments, and/or methods according to the present disclosure, are intended to convey that the described component, feature, detail, structure, embodiment, and/or method is an illustrative, non-exclusive example of components, features, details, structures, embodiments, and/or methods according to the present disclosure. Thus, the described component, feature, detail, structure, embodiment, and/or method is not intended to be limiting, required, or exclusive/exhaustive; and other components, features, details, structures, embodiments, and/or methods, including structurally and/or functionally similar and/or equivalent components, features, details, structures, embodiments, and/or methods, are also within the scope of the present disclosure.

As used herein, “at least substantially,” when modifying a degree or relationship, may include not only the recited “substantial” degree or relationship, but also the full extent of the recited degree or relationship. A substantial amount of a recited degree or relationship may include at least 75% of the recited degree or relationship. For example, an object that is at least substantially formed from a material includes objects for which at least 75% of the objects are formed from the material and also includes objects that are completely formed from the material. As another example, a first length that is at least substantially as long as a second length includes first lengths that are within 75% of the second length and also includes first lengths that areas long as the second length.

Illustrative, non-exclusive examples of measurement module adapters, probe assemblies, probe systems, and methods according to the present disclosure are presented in the following enumerated paragraphs. It is within the scope of the present disclosure that an individual step of a method recited herein, including in the following enumerated paragraphs, may additionally or alternatively be referred to as a “step for” performing the recited action.

A1. A measurement module adapter configured to operatively attach a measurement module and a probe arm to a manipulator of a probe system, the measurement module adapter comprising:
an adapter plate that includes:
(i) a manipulator-facing surface that defines an adapter plate mount configured to be operatively attached to the manipulator; and
(ii) a module-facing surface that defines a bracket assembly mount;
a bracket assembly selectively and operatively affixed to the bracket assembly mount, wherein the bracket assembly includes a plurality of insert-receiving regions, and further wherein the measurement module adapter is configured to selectively permit adjustment of a relative orientation between the bracket assembly and the adapter plate along a first adjustment axis;
a plurality of inserts, wherein a corresponding insert of the plurality of inserts:
(i) is selectively and operatively attached to the bracket assembly within a corresponding insert-receiving region of the plurality of insert-receiving regions, optionally via a corresponding plurality of insert-receiving region fasteners; and
(ii) includes a corresponding insert fastener configured to be operatively attached to the measurement module, wherein each insert and the corresponding insert-receiving region together are configured to permit adjustment of a relative orientation between the corresponding insert fastener and the bracket assembly along a second adjustment axis that extends perpendicular, or at least substantially perpendicular, to the first adjustment axis; and
a probe arm mount configured to be operatively attached to the probe arm.

A2. The measurement module adapter of paragraph A1, wherein the adapter plate mount defines an adapter plate mount plane, wherein the module-facing surface defines a module-facing surface plane, and further wherein the adapter plate mount plane is oriented at an angle relative to the module-facing surface plane.

A3. The measurement module adapter of paragraph A2, wherein the angle is at least one of:
(i) at least 10 degrees, at least 15 degrees, at least 20 degrees, at least 25 degrees, at least 30 degrees, at least 35 degrees, at least 40 degrees, at least 45 degrees, or at least 50 degrees; and
(ii) at most 80 degrees, at most 75 degrees, at most 70 degrees, at most 65 degrees, at most 60 degrees, at most 55 degrees, at most 50 degrees, at most 45 degrees, or at most 40 degrees.

A4. The measurement module adapter of any of paragraphs A1-A3, wherein the module-facing surface defines a/the module-facing surface plane, wherein the first adjustment axis extends parallel, or at least substantially parallel, to the module-facing surface plane, and further wherein the second adjustment axis extends parallel, or at least substantially parallel, to the module-facing surface plane.

A5. The measurement module adapter of any of paragraphs A1-A4, wherein the adapter plate mount at least one of:
(i) defines a fixed orientation with respect to a remainder of the adapter plate; and
(ii) defines a fixed adapter plate mounting configuration that is based, at least in part, on a geometry of the manipulator.

A6. The measurement module adapter of any of paragraphs A1-A5, wherein the adapter plate mount includes an adapter plate mount fastener-receiving region configured to receive an adapter plate mount fastener that is configured to operatively attach, and optionally pivotally attach, the adapter plate to the manipulator via the adapter plate mount, optionally wherein the adapter plate mount is configured to indirectly attach the adapter plate to the manipulator via an intermediate mount.

A7. The measurement module adapter of any of paragraphs A1-A6, wherein the probe arm mount at least one of:
(i) extends from the manipulator-facing surface; and
(ii) is defined on the manipulator-facing surface.

A8. The measurement module adapter of any of paragraphs A1-A7, wherein the adapter plate is a unitary, a monolithic, and/or a single-piece adapter plate that defines the manipulator-facing surface, the adapter plate mount, the module-facing surface, and the bracket assembly mount.

A9. The measurement module adapter of paragraph A8, wherein the unitary, the monolithic, and/or the single-piece adapter plate further defines the probe arm mount.

A10. The measurement module adapter of any of paragraphs A1-A9, wherein the module-facing surface is a planar, at least partially planar, or at least substantially planar, module-facing surface.

A11. The measurement module adapter of any of paragraphs A1-A10, wherein the bracket assembly mount includes an elongate slot that extends along the first adjustment axis, optionally wherein the elongate slot includes an elongate T-slot.

A12. The measurement module adapter of any of paragraphs A1-A11, wherein the bracket assembly mount includes a pair of parallel, or at least substantially parallel, elongate slots that extends parallel to the first adjustment axis, optionally wherein the pair of parallel elongate slots includes a pair of parallel elongate T-slots.

A13. The measurement module adapter of paragraph A12, wherein the pair of parallel elongate slots is spaced apart from one another.

A14. The measurement module adapter of any of paragraphs A12-A13, wherein each elongate slot of the pair of parallel elongate slots extends along a corresponding side of the module-facing surface.

A15. The measurement module adapter of any of paragraphs A12-A14, wherein the bracket assembly mount further includes a plurality of bracket assembly mount fasteners, wherein each bracket assembly mount fastener of the plurality of bracket assembly mount fasteners is positioned at least partially within a corresponding elongate slot of the pair of parallel elongate slots and is affixed to the bracket assembly, and further wherein each bracket assembly mount fastener is configured to be loosened to permit adjustment of the relative orientation between the bracket assembly and the adapter plate along the first adjustment axis and to be tightened to resist the adjustment.

A16. The measurement module adapter of any of paragraphs A12-A15, wherein the pair of parallel elongate slots is a first pair of parallel elongate slots, and further wherein the bracket assembly mount includes a second pair of parallel, or at least substantially parallel, elongate slots that extends parallel to the first adjustment axis.

A17. The measurement module adapter of paragraph A16, wherein the first pair of parallel elongate slots and the second pair of parallel elongate slots are spaced apart from one another along the first adjustment axis.

A18. The measurement module adapter of any of paragraphs A16-A17, wherein the bracket assembly is selectively and operatively affixed to the bracket assembly mount via both the first pair of parallel elongate slots and the second pair of parallel elongate slots.

A19. The measurement module adapter of any of paragraphs A1-A18, wherein the bracket assembly mount is configured to permit adjustment of the relative orientation between at least a component of the bracket assembly and the adapter plate through a first adjustment axis range-of-motion of at least one of:
(i) at least 100 millimeters (mm), at least 125 mm, at least 150 mm, at least 175 mm, or at least 200 mm; and
(ii) at most 400 mm, at most 375 mm, at most 350 mm, at most 325 mm, at most 300 mm, at most 275 mm, at most 250 mm, at most 225 mm, or at most 200 mm.

A20. The measurement module adapter of any of paragraphs A1-A19, wherein the probe arm mount is at least partially defined by the bracket assembly.

A21. The measurement module adapter of any of paragraphs A1-A20, wherein the bracket assembly includes a probe-distal bracket configured to be operatively attached to the bracket assembly mount.

A22. The measurement module adapter of paragraph A21, wherein the measurement module adapter is configured to selectively permit adjustment of a relative orientation between the probe-distal bracket and the adapter plate along the first adjustment axis.

A23. The measurement module adapter of any of paragraphs A21-A22, wherein the probe-distal bracket is configured to be operatively attached to a probe-distal end region of the measurement module.

A24. The measurement module adapter of any of paragraphs A21-A23, wherein the probe-distal bracket includes a pair of probe-distal insert-receiving regions of the plurality of insert-receiving regions.

A25. The measurement module adapter of paragraph A24, wherein the corresponding insert is selectively and operatively attached to the bracket assembly within each probe-distal insert-receiving region.

A26. The measurement module adapter of any of paragraphs A1-A25, wherein the bracket assembly includes a probe-proximate bracket configured to be operatively attached to the bracket assembly mount.

A27. The measurement module adapter of paragraph A26, wherein the measurement module adapter is configured to selectively permit adjustment of a relative orientation between the probe-proximate bracket and the adapter plate along the first adjustment axis.

A28. The measurement module adapter of any of paragraphs A26-A27, wherein the probe-proximate bracket is configured to be operatively attached to a probe-proximate end region of the measurement module.

A29. The measurement module adapter of any of paragraphs A26-A28, wherein the probe-proximate bracket includes a pair of probe-proximate insert-receiving regions of the plurality of insert-receiving regions.

A30. The measurement module adapter of paragraph A29, wherein the corresponding insert is selectively and operatively attached to the bracket assembly within each probe-proximate insert-receiving region.

A31. The measurement module adapter of any of paragraphs A26-A30, wherein the probe arm mount is at least partially defined by the probe-proximate bracket.

A31.1. The measurement module adapter of any of paragraphs A26-A31, wherein the measurement module adapter is configured to permit independent adjustment of the relative orientation between the probe-distal bracket and the adapter plate along the first adjustment axis and of the relative orientation between the probe-proximate bracket and the adapter plate along the first adjustment axis.

A32. The measurement module adapter of any of paragraphs A1-A31.1, wherein the bracket assembly further includes an intermediate bracket configured to be operatively attached to the bracket assembly mount.

A33. The measurement module adapter of paragraph A32, wherein the measurement module adapter is configured to selectively permit adjustment of a relative orientation between the intermediate bracket and the adapter plate along the first adjustment axis.

A34. The measurement module adapter of any of paragraphs A32-A33, wherein the intermediate bracket is configured to be operatively attached to a probe-distal end region of the measurement module, wherein the measurement module is a first measurement module, and further wherein a/the probe-distal bracket of the bracket assembly is configured to be operatively attached to a second measurement module that is distinct from the first measurement module.

A35. The measurement module adapter of any of paragraphs A32-A34, wherein the intermediate bracket includes a pair of intermediate insert-receiving regions of the plurality of insert-receiving regions.

A36. The measurement module adapter of paragraph A35, wherein the corresponding insert is selectively and operatively attached to the bracket assembly within each intermediate insert-receiving region.

A37. The measurement module adapter of any of paragraphs A1-A36, wherein at least a subset of the plurality of insert-receiving regions is sized to receive the corresponding insert at a single, or only a single, relative orientation within the corresponding insert-receiving region.

A38. The measurement module adapter of any of paragraphs A1-A37, wherein at least a subset of the plurality of insert-receiving regions is oversized with respect to the corresponding insert and is sized to receive the corresponding insert in a plurality of different relative orientations along at least one of the first adjustment axis and the second adjustment axis.

A39. The measurement module adapter of any of paragraphs A1-A38, wherein at least a subset of the plurality of insert-receiving regions includes an insert attachment channel, or a pair of opposed insert attachment channels, configured to facilitate selective and operative attachment of the corresponding insert at a plurality of spaced apart locations along a length of the insert attachment channel, or of the pair of opposed insert attachment channels.

A40. The measurement module adapter of any of paragraphs A1-A39, wherein at least a subset of the plurality of insert-receiving regions is configured to permit selective translation of the corresponding insert along one of the first adjustment axis and the second adjustment axis through an insert range-of-motion of at least one of:
(i) at least 20 mm, at least 30 mm, at least 40 mm, at least 50 mm, at least 60 mm, at least 70 mm, at least 80 mm, or at least 90 mm; and
(ii) at most 150 mm, at most 140 mm, at most 130 mm, at most 120 mm, at most 110 mm, at most 100 mm, at most 90 mm, or at most 80 mm.

A41. The measurement module adapter of any of paragraphs A1-A40, wherein at least a subset of the plurality of inserts includes an insert base that defines an insert opening, wherein the insert base is sized to be received within the corresponding insert-receiving region, and further wherein the corresponding insert fastener is received within the insert opening.

A42. The measurement module adapter of paragraph A41, wherein the insert opening includes an insert fastener slot, and further wherein the insert fastener slot is sized to permit translation of the corresponding insert fastener relative to the insert base along one of the first adjustment axis and the second adjustment axis.

A43. The measurement module adapter of paragraph A42, wherein the insert fastener slot is sized to permit translation of the corresponding insert fastener through an insert fastener range-of-motion of at least one of:
(i) at least 20 mm, at least 30 mm, at least 40 mm, at least 50 mm, at least 60 mm, at least 70 mm, at least 80 mm, or at least 90 mm; and
(ii) at most 150 mm, at most 140 mm, at most 130 mm, at most 120 mm, at most 110 mm, at most 100 mm, at most 90 mm, or at most 80 mm.

A44. The measurement module adapter of any of paragraphs A1-A43, wherein at least a subset of the plurality of inserts includes visual indicia indicative of at least one of:
(i) a size of the corresponding insert fastener;
(ii) a thread pitch of the corresponding insert fastener;
(iii) an identity of the measurement module; and
(iv) a desired position of the corresponding insert fastener for attachment to the measurement module.

A45. The measurement module adapter of any of paragraphs A1-A44, wherein the measurement module is a first measurement module, wherein the plurality of inserts is a first set of inserts configured to be operatively attached to the first measurement module, wherein the measurement module adapter includes a plurality of sets of inserts, and further wherein each set of inserts of the plurality of sets of inserts at least partially differs from each other set of inserts of the plurality of sets of inserts and is configured to be operatively attached to a corresponding measurement module of a plurality of distinct measurement modules.

B1. A probe assembly, comprising:
a manipulator;
the measurement module adapter of any of paragraphs A1-A45, wherein the adapter plate mount is at least one of directly and indirectly operatively attached to the manipulator;
a probe arm operatively attached to the probe arm mount;
a probe operatively attached to the probe arm; and
a measurement module operatively attached to the bracket assembly via the corresponding insert fastener of the plurality of inserts.

B2. The probe assembly of paragraph B1, wherein the probe assembly further includes a signal conduit extending from the measurement module to the probe and configured to convey a signal between the measurement module and the probe.

B3. The probe assembly of any of paragraphs B1-B2, wherein the measurement module includes at least one of a vector network analyzer frequency extender, a spectrum analyzer frequency extender, an rf source frequency extender, a noise parameter frequency extender, a load and source pull frequency extender, and a noise module.

B4. The probe assembly of any of paragraphs B1-B3, wherein the measurement module is a first measurement module, and further wherein the probe assembly includes a second measurement module operatively attached to the bracket assembly.

B5. The probe assembly of paragraph B4, when dependent from paragraph B2, wherein the signal conduit is a first signal conduit, and further wherein the probe assembly includes a second signal conduit extending from the measurement module to at least one of the probe and the first measurement module.

C1. A probe system configured to test a device under test (DUT), the probe system comprising:
a chuck that defines a support surface configured to support a substrate that includes the DUT;
a manipulator mounting surface; and the probe assembly of any of paragraphs B1-B5, wherein the manipulator is operatively attached to the manipulator mounting surface.

C2. The probe system of paragraph C1, wherein the probe system further includes a signal generation and analysis assembly configured to at least one of:
(i) provide a test signal to the DUT via the measurement module;
(ii) receive a resultant signal from the DUT via the measurement module;
(iii) provide a test signal to the DUT via the probe; and
(iv) receive a resultant signal from the DUT via the probe.

D1. A method of utilizing a probe system, the method comprising:
disconnecting an initial measurement module from a probe of the probe system via disconnection of an initial signal conduit from at least one of the initial measurement module and the probe;
detaching the initial measurement module from a measurement module adapter of the probe system via disengagement of an initial plurality of insert fasteners of the measurement module adapter from the initial measurement module;
adjusting the measurement module adapter to interface with a subsequent measurement module, which differs from the initial measurement module, by at least one of:
(i) operatively translating at least one insert fastener of the initial plurality of insert fasteners relative to at least one other insert fastener of the initial plurality of insert fasteners and within a translation plane that is parallel to a bracket assembly mount of the measurement module adapter; and
(ii) replacing at least one insert of the measurement module adapter with a structurally different insert of the measurement module adapter;
attaching the subsequent measurement module to the measurement module adapter via engagement of a subsequent plurality of insert fasteners of the measurement module adapter with the subsequent measurement module; and connecting the subsequent measurement module to the probe via a subsequent signal conduit.

D2. The method of paragraph D1, wherein the operatively translating includes at least one of:
(i) operatively translating at least one insert base of at least one insert of the measurement module adapter, which includes the at least one insert fastener, within a corresponding insert-receiving region of the measurement module adapter;
(ii) operatively translating the at least one insert fastener within an insert fastener slot of the at least one insert base;
(iii) operatively translating a probe-distal bracket of the measurement module adapter relative to an adapter plate of the measurement module adapter; and
(iv) operatively translating a probe-proximate bracket of the measurement module adapter relative to the adapter plate.

D3. The method of any of paragraphs D1-D2, wherein the adjusting includes utilizing at least one visual indicia of the measurement module adapter to guide the adjusting.

D4. The method of any of paragraphs D1-D3, wherein the replacing includes selecting the structurally different insert from a plurality of inserts of the measurement module adapter.

D5. The method of paragraph D4, wherein the selecting includes utilizing at least one visual indicia of the structurally different insert.

D6. The method of any of paragraphs D1-D5, wherein, prior to the disconnecting the initial measurement module from the probe and the detaching the initial measurement module from the measurement module adapter, the method further includes performing an initial test on an initial device under test utilizing the probe system.

D7. The method of paragraph D6, wherein, subsequent to the connecting the subsequent measurement module to the probe and the attaching the subsequent measurement module to the measurement module adapter, the method further includes performing a subsequent test, which differs from the initial test, on a subsequent device under test utilizing the probe system.

D8. The method of paragraph D7, wherein the initial device under test differs from the subsequent device under test.

D9. The method of paragraph D7, wherein the initial device under test and the subsequent device under test are the same device under test.

D10. The method of any of paragraphs D1-D9, wherein the initial signal conduit differs from the subsequent signal conduit.

D11. The method of any of paragraphs D1-D9, wherein the initial signal conduit and the subsequent signal conduit are the same signal conduit.

D12. The method of any of paragraphs D1-D11, wherein the initial plurality of insert fasteners differs from the subsequent plurality of insert fasteners.

D13. The method of any of paragraphs D1-D11, wherein the initial plurality of insert fasteners and the subsequent plurality of insert fasteners are the same plurality of insert fasteners.

D14. The method of any of paragraphs D1-D13, wherein the probe system includes any suitable structure, function, and/or feature of any of the measurement module adapters of any of paragraphs A1-A45, any of the probe assemblies of any of paragraphs B1-B5, or any of the probe systems of any of paragraphs C1-C2.

### INDUSTRIAL APPLICABILITY

The measurement module adapters, probe assemblies, probe systems, and methods disclosed herein are applicable to the semiconductor manufacturing and test industries.

It is believed that the disclosure set forth above encompasses multiple distinct inventions with independent utility. While each of these inventions has been disclosed in its preferred form, the specific embodiments thereof as disclosed and illustrated herein are not to be considered in a limiting sense as numerous variations are possible. The subject matter of the inventions includes all novel and non-obvious combinations and subcombinations of the various elements, features, functions and/or properties disclosed herein. Similarly, where the claims recite “a” or “a first” element or the equivalent thereof, such claims should be understood to include incorporation of one or more such elements, neither requiring nor excluding two or more such elements.

It is believed that the following claims particularly point out certain combinations and subcombinations that are directed to one of the disclosed inventions and are novel and non-obvious. Inventions embodied in other combinations and subcombinations of features, functions, elements and/or properties may be claimed through amendment of the present claims or presentation of new claims in this or a related application. Such amended or new claims, whether they are directed to a different invention or directed to the same invention, whether different, broader, narrower, or equal in scope to the original claims, are also regarded as included within the subject matter of the inventions of the present disclosure.

1. A measurement module adapter configured to operatively attach a measurement module and a probe arm to a manipulator of a probe system, the measurement module adapter comprising:
an adapter plate that includes:
(i) a manipulator-facing surface that defines an adapter plate mount configured to be operatively attached to the manipulator; and
(ii) a module-facing surface that defines a bracket assembly mount;
a bracket assembly selectively and operatively affixed to the bracket assembly mount, wherein the bracket assembly includes a plurality of insert-receiving regions, and further wherein the measurement module adapter is configured to selectively permit adjustment of a relative orientation between the bracket assembly and the adapter plate along a first adjustment axis;
a plurality of inserts, wherein a corresponding insert of the plurality of inserts:
(i) is selectively and operatively attached to the bracket assembly within a corresponding insert-receiving region of the plurality of insert-receiving regions; and
(ii) includes a corresponding insert fastener configured to be operatively attached to the measurement module, wherein each insert and the corresponding insert-receiving region together are configured to permit adjustment of a relative orientation between the corresponding insert fastener and the bracket assembly along a second adjustment axis that extends at least substantially perpendicular to the first adjustment axis; and
a probe arm mount configured to be operatively attached to the probe arm.

2. The measurement module adapter of claim 1, wherein the adapter plate mount defines an adapter plate mount plane, wherein the module-facing surface defines a module-facing surface plane, and further wherein the adapter plate mount plane is oriented at an angle relative to the module-facing surface plane.

3. The measurement module adapter of claim 1, wherein the module-facing surface defines a module-facing surface plane, wherein the first adjustment axis extends at least substantially parallel to the module-facing surface plane, and further wherein the second adjustment axis extends at least substantially parallel to the module-facing surface plane.

4. The measurement module adapter of claim 1, wherein the adapter plate mount includes an adapter plate mount fastener-receiving region configured to receive an adapter plate mount fastener that is configured to pivotally attach the adapter plate to the manipulator via the adapter plate mount.

5. The measurement module adapter of claim 1, wherein the probe arm mount at least one of:
(i) extends from the manipulator-facing surface; and
(ii) is defined on the manipulator-facing surface.

6. The measurement module adapter of claim 1, wherein the bracket assembly mount includes a pair of at least substantially parallel elongate slots that is spaced-apart from one another and extends parallel to the first adjustment axis.

7. The measurement module adapter of claim 6, wherein the bracket assembly mount further includes a plurality of bracket assembly mount fasteners, wherein each bracket assembly mount fastener of the plurality of bracket assembly mount fasteners is positioned at least partially within a corresponding elongate slot of the pair of at least substantially parallel elongate slots and is affixed to the bracket assembly, and further wherein each bracket assembly mount fastener is configured to be loosened to permit adjustment of the relative orientation between the bracket assembly and the adapter plate along the first adjustment axis and to be tightened to resist the adjustment.

8. The measurement module adapter of claim 1, wherein the probe arm mount is at least partially defined by the bracket assembly.

9. The measurement module adapter of claim 1, wherein the bracket assembly includes a probe-distal bracket configured to be operatively attached to the bracket assembly mount, wherein the probe-distal bracket is configured to be operatively attached to a probe-distal end region of the measurement module, wherein the bracket assembly further includes a probe-proximate bracket configured to be operatively attached to the bracket assembly mount, wherein the probe-proximate bracket is configured to be operatively attached to a probe-proximate end region of the measurement module, and further wherein the measurement module adapter is configured to permit independent adjustment of the relative orientation between the probe-distal bracket and the adapter plate along the first adjustment axis and of the relative orientation between the probe-proximate bracket and the adapter plate along the first adjustment axis.

10. The measurement module adapter of claim 1, wherein at least a subset of the plurality of insert-receiving regions is sized to receive the corresponding insert at only a single relative orientation within the corresponding insert-receiving region.

11. The measurement module adapter of claim 1, wherein at least a subset of the plurality of insert-receiving regions is oversized with respect to the corresponding insert and is sized to receive the corresponding insert in a plurality of different relative orientations along at least one of the first adjustment axis and the second adjustment axis.

12. The measurement module adapter of claim 1, wherein at least a subset of the plurality of inserts includes visual indicia indicative of at least one of:
(i) a size of the corresponding insert fastener;
(ii) a thread pitch of the corresponding insert fastener;
(iii) an identity of the measurement module; and
(iv) a desired position of the corresponding insert fastener for attachment to the measurement module.

13. The measurement module adapter of claim 1, wherein the measurement module is a first measurement module, wherein the plurality of inserts is a first set of inserts configured to be operatively attached to the first measurement module, wherein the measurement module adapter includes a plurality of sets of inserts, and further wherein each set of inserts of the plurality of sets of inserts at least partially differs from each other set of inserts of the plurality of sets of inserts and is configured to be operatively attached to a corresponding measurement module of a plurality of distinct measurement modules.

14. A probe assembly, comprising:
a manipulator;
the measurement module adapter of claim 1, wherein the adapter plate mount is operatively attached to the manipulator;
a probe arm operatively attached to the probe arm mount;
a probe operatively attached to the probe arm; and
a measurement module operatively attached to the bracket assembly via the corresponding insert fastener of the plurality of inserts.

15. The probe assembly of claim 14, wherein the measurement module includes at least one of a vector network analyzer frequency extender, a spectrum analyzer frequency extender, an rf source frequency extender, a noise parameter frequency extender, a load and source pull frequency extender, and a noise module.

16. The probe assembly of claim 14, wherein the measurement module is a first measurement module, and further wherein the probe assembly includes a second measurement module operatively attached to the bracket assembly.

17. A probe system configured to test a device under test (DUT), the probe system comprising:
a chuck that defines a support surface configured to support a substrate that includes the DUT;
a manipulator mounting surface; and
the probe assembly of claim 14, wherein the manipulator is operatively attached to the manipulator mounting surface.

18. The probe system of claim 17, wherein the probe system further includes a signal generation and analysis assembly configured to at least one of:
(i) provide a test signal to the DUT via the measurement module;
(ii) receive a resultant signal from the DUT via the measurement module;
(iii) provide a test signal to the DUT via the probe; and
(iv) receive a resultant signal from the DUT via the probe.

19. A method of utilizing a probe system, the method comprising:
disconnecting an initial measurement module from a probe of the probe system via disconnection of an initial signal conduit from at least one of the initial measurement module and the probe;
detaching the initial measurement module from a measurement module adapter of the probe system via disengagement of an initial plurality of insert fasteners of the measurement module adapter from the initial measurement module;
adjusting the measurement module adapter to interface with a subsequent measurement module, which differs from the initial measurement module, by at least one of:
(i) operatively translating at least one insert fastener of the initial plurality of insert fasteners relative to at least one other insert fastener of the initial plurality of insert fasteners and within a translation plane that is parallel to a bracket assembly mount of the measurement module adapter; and
(ii) replacing at least one insert of the measurement module adapter with a structurally different insert of the measurement module adapter;
attaching the subsequent measurement module to the measurement module adapter via engagement of a subsequent plurality of insert fasteners of the measurement module adapter with the subsequent measurement module; and
connecting the subsequent measurement module to the probe via a subsequent signal conduit.

20. The method of claim 19, wherein the operatively translating includes at least one of:
(i) operatively translating at least one insert base of at least one insert of the measurement module adapter, which includes the at least one insert fastener, within a corresponding insert-receiving region of the measurement module adapter;
(ii) operatively translating the at least one insert fastener within an insert fastener slot of the at least one insert base;
(iii) operatively translating a probe-distal bracket of the measurement module adapter relative to an adapter plate of the measurement module adapter; and
(iv) operatively translating a probe-proximate bracket of the measurement module adapter relative to the adapter plate.
